(19) United States
(12) Patent Application Publication
(10) Pub. No.: US 2024/0248142 A1
(43) Pub. Date: Jul. 25, 2024

(54) BATTERY OPTIMIZATION IN A WIRELESS DISPLAY DEVICE

(71) Applicant: Displace, Inc., Cupertino, CA (US)

(72) Inventors: Balaji Krishnan, Cupertino, CA (US); Corey Axelowitz, San Diego, CA (US); Philippe Williamson, San Diego, CA (US); Erik Danielson, San Diego, CA (US)

(21) Appl. No.: 18/421,980

(22) Filed: Jan. 24, 2024

Related U.S. Application Data
(60) Provisional application No. 63/440,869, filed on Jan. 24, 2023.

(51) Int. Cl. G01R 31/382; G01R 31/392

(52) U.S. Cl. CPC G01R 31/382; G01R 31/392

(57) ABSTRACT

Techniques for optimizing battery usage in one or more wireless display devices are provided. In one technique, a current charge of each insertable battery in a wireless display device is identified. A current charge of each internal battery in the wireless display device is identified. Based on the current charges, it is determined whether power (or charge) from an insertable battery should be transferred to one of the internal batteries. In another technique, one or more first batteries in a display device are determined to be in a blocked state and one or more second batteries in the display device are determined to be unblocked state. Based on these determinations, the one or more second batteries are used before the one or more first batteries or power from the one or more second batteries is transferred electrical power to at least one of the one or more first batteries.

### CROSS-REFERENCE TO RELATED APPLICATION; BENEFIT CLAIM

This application claims the benefit of U.S. Provisional Patent Application No. 63/440,869, filed Jan. 24, 2023, the entire contents of which is hereby incorporated by reference as if fully set forth herein, under 35 U.S.C. § 119(e).

This application is related to U.S. patent application Ser. No. 18/421,981, entitled “MODULAR SELF-AWARE BATTERY-POWERED WIRELESS DISPLAY DEVICES,” filed Jan. 24, 2024, the entire contents of which are hereby incorporated by reference as if fully set forth herein.

This application is related to U.S. patent application Ser. No. 18/421,978, entitled “WIRELESS TV ARCHITECTURE,” filed Jan. 24, 2024, the entire contents of which are hereby incorporated by reference as if fully set forth herein.

This application is related to U.S. patent application Ser. No. 18/421,974, entitled “ATTACHING A WIRELESS DISPLAY DEVICE TO A VERTICAL SURFACE,” filed Jan. 24, 2024, the entire contents of which are hereby incorporated by reference as if fully set forth herein.

### TECHNICAL FIELD

The present disclosure relates to television display systems and, more particularly, to a battery-powered, wireless display device.

### BACKGROUND

Current television systems rely on wires to connect to power and to receive television and other content data, and therefore, restrict the location of display devices. Such systems also rely on technology of third parties to control content and often control display options.

### BRIEF DESCRIPTION OF THE DRAWINGS

FIG. 1 is a block diagram that depicts an example display system, in an embodiment;

FIG. 2 is a flow diagram that depicts an example process for optimizing battery usage in a wireless display device, in an embodiment;

FIG. 3 is a flow diagram that depicts an example process 300 for optimizing battery usage, in an embodiment;

FIG. 4 is a flow diagram that depicts an example process for optimizing battery usage among multiple display devices, in an embodiment;

FIGS. 5A-5B are diagrams that depict a non-screen side of an example display device that implements a vacuum mechanism, in an embodiment;

FIG. 6 is a flow diagram that depicts an example process 600 for a wireless display device deploying multiple adhesion (or attachment) mechanisms, in an embodiment;

FIG. 7 is a flow diagram that depicts an example process for a wireless display device deploying a vacuum mechanism, in an embodiment;

FIG. 8 is a flow diagram that depicts an example process for automatically lowering a wireless display device that was attached to a vertical surface, in an embodiment;

FIG. 9 is a flow diagram that depicts an example process for sharing content among two or more display devices, in an embodiment;

FIG. 10 is a block diagram that illustrates computer system upon which various embodiments may be implemented;

FIG. 11 is a block diagram of basic software system that may be employed for controlling the operation of the computer system.

### DETAILED DESCRIPTION

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

### General Overview

A system and method for providing battery-powered wireless display devices are described. A display device is part of a display system for presenting television, live broadcast, streaming, and Internet content to users. The display system may include a centralized computer architecture that communicates wirelessly with one or more wireless display devices that are battery-powered and, in embodiments, include attachment mechanisms for attaching to (and detaching from) vertical surfaces.

Embodiments improve computer-related technology by allowing a completely wireless display device to be moved from one vertical surface to another with ease, without requiring traditional mounting methods that are laborious and without requiring proximity to electrical outlets.

### Display System Over View

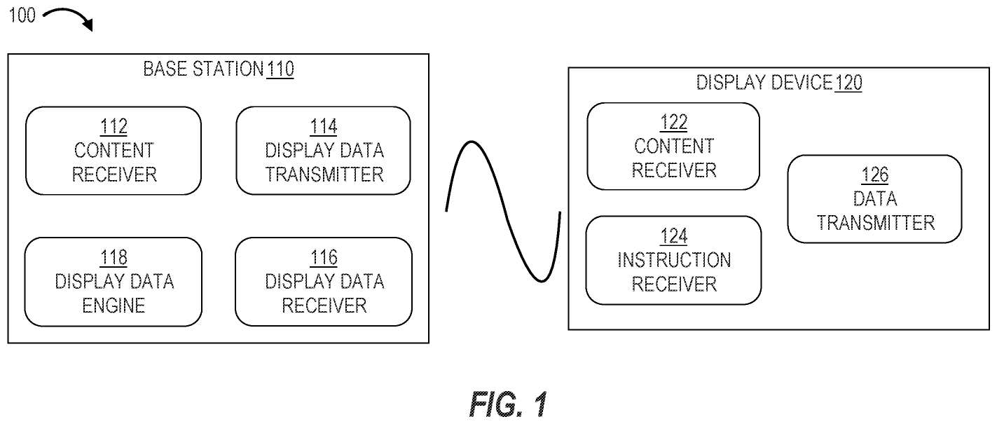

FIG. 1 is a block diagram that depicts an example display system 100, in an embodiment. Display system 100 comprises a base station 110 and a display device 120 (or simply “display 120”). Base station 110 is a computing device that is communicatively coupled to display 120 wirelessly, such as via WiFi. Although only a single display 120 is depicted, display system 100 may include multiple displays. Base station 110 may be small enough to fit in a small location that is not visible to the average person traversing common areas of a geographic location, such as a home. For example, base station 110 may fit in a cleaning closet, in a bedroom closet, in an attic, or under a bed. In contrast, display 120 may be much larger than base station 110.

Base station 110 includes a content receiver 112 for receiving digital content from one or more external digital content sources (not depicted), such as a cable network, a satellite network, a television network, a streaming service, a website, etc. Thus, base station 110 may be communicatively coupled to the Internet through a content service provider (not depicted). An example operating system of base station 110 is a Linux-based operation system, but embodiments are not so limited.

Base station 110 also includes a display data transmitter 114 for wirelessly transmitting digital data to display 120, and a display data receiver 116 for receiving data from display 120. Transmitter 114 may have limited range such that a display that is outside of that range is unable to consistently receive digital content from transmitter 114. Therefore, base station 110 may be placed in a physical location such that display 120, regardless of their location within a structure (e.g., a home or office), are still in range of base station 110.

Base station 110 also includes a display engine 118 that renders data from certain content providers (e.g., websites) and causes the rendered data to be presented on a display. Display engine 118 may receive a uniform resource locator (URL) from display 120 or from a server that is communicatively coupled to a user's personal device. Display engine 118 requests data from the URL (which is associated with a content provider) and performs formatting operations on the received data so that the data is rendered in a visually appealing way on display 120. If the URL is not of a known content provider, then display engine 118 may not perform any formatting on the received data from that URL. Instead, display engine 118 may leverage a web browser to render the received data and cause the web browser rendered data to be presented on display 120.

Display 120 is a device that includes a content receiver 122 for wirelessly receiving content data from base station 110, an instruction receiver 124 for wirelessly receiving instruction data from base station 110, a data transmitter 126 for wirelessly transmitting data to base station 110 (e.g., data about current battery life of each battery inserted in display 120, digital audio data of a voice command from a user of display 120, a digital image of a user of display 120 for facial recognition, attachment/adhesion status of display 120 to a vertical surface, free stand status indicating whether display 120 is connected to a stand (or, for example, leaning on a wall) rather than attached to a vertical surface, connection (or snap status) of display 120 to one or more other displays), and a screen for displaying image (including video) content (included in digital data received from base station 110). The screen of display 120 may be of any size, such as 32 inches (as measured on the diagonal), 55 inches, or larger. The screen of display 120 may cover the entirety (or nearly the entirety) of one side of display 120, such that 95% or more of the area of that side is contiguous screen.

Content receiver 122, instruction receiver 124, and data transmitter 126 may be implemented in hardware or a combination of hardware and software. While content receiver 122 and instruction receiver 124 are depicted as separate components of display 120, they may be the same component. However, in an embodiment, the two receivers are separate components and receive the different types of data on different frequencies or channels, so that content receiving and presentation on a screen of display 120 may occur without interruption in case base station 110 also sends instructions to display 120 to perform one or more operations other than presenting content.

Display 120 may also include one or more speakers for playing audio content (included in digital data received from base station 110), one or more microphones for receiving audio data (e.g., in the form of voice commands of a human user) from the immediate physical environment of display 120, and one or more cameras for capturing image or video data of the immediate physical environment. For example, a camera integrated within display 120 may take a digital photo of a user's face and transmit the digital photo to base station 110, which performs facial recognition on the digital photo to allow the user access to digital data or functionality of display 120. As another example, a microphone integrated within display 120 may receive voice commands, convert the voice commands to digital voice commands, and transmit the digital voice commands to base station 110, which performs voice recognition on the digital voice commands to verify an identity of an authorized user of display 120.

In an embodiment, base station 110 includes logic for controlling different functions of display 120. Display 120 sends status information to base station 110 and forwards, to base station 110, any commands received from the user, whether received visually using a camera of display 120, audibly using a microphone of display 120, or wirelessly using a receiver of display 120 to receive wireless instructions from a device of the user, such as (a) a remote control that comes with display 120 or (b) a personal device executing a software application that is configured to communicate with the display or base station 110.

In an embodiment of multiple displays 120, each display 120 is connected to base station 110 is part of a private mesh network controlled by base station 110 to enable modularity and interaction on the fly. In a related embodiment, each display 120 includes a WiFi extender that effectively extends the perimeter of the mesh network. A WiFi 7 or WiFi 6E implementation as a mesh network allows base station 110 to communicate with each display 120 individually, as well as a group, thereby enabling a display to be coupled to another display to either expand the capabilities of one of the receivers or displays or to enable different displays to be shown separately, in accordance with the programming instructions received by base station 110.

### Display-Only Embodiment

In an embodiment, a display system does not include a base station. Instead, a display system only includes one or more displays. Each display fetches content from a wireless source (e.g., via WiFi) and presents the content on its own. In a related embodiment, if a base station is introduced to the display system, then each display discovers the base station, creates a wireless connection with the base station, and, thereafter, receives content and instructions from the base station. A base station and a display may discover each other by periodically sending a discover beacon notification that includes identification data that identifies the sending device. A (receiving) device that receives a discover beacon notification, if the device is in a discovery mode, responds to the discover beacon notification with identification data that identifies the receiving device. The sending device knows that a message from another device that includes the sending device's identification data and the other device's identification data is a newly discovered device.

In a related embodiment, each display in a multi-display display system discovers each other display if the other display is in wireless range of the display. Thus, each display establishes a peer-to-peer connection with each other display in a display system. Once a peer-to-peer connection is established, each connected display is able to independently transfer content and data to the other connected display. A transfer from one display may be a one-to-one transfer or a one-to-many transfer. Thus, one display may transfer the same content and/or other data to multiple displays at the same time.

### Hot Swappable Batteries

In an embodiment, each display 120 includes one or more battery bays. Example batteries that may be inserted into the battery bays include lithium ion batteries, lithium polymer batteries, and hydrogen fuel cells. Four lithium ion batteries or lithium polymer batteries enable a full month of viewing (without having to switch batteries) with an average of six hours usage per day. Also, a display that includes four lithium-based batteries inserted therein may be less than 21 pounds in weight.

In an embodiment, each battery is a hot swappable battery, which is a power source that can be swapped out without interrupting the normal operation of a device. Thus, a display may include two or more battery bays, each for a hot swappable (or “insertable”) battery. Several battery bays may be coupled to the display such that only one battery is required to operate the display at any given time. Thus, while a battery may be disconnected from one battery bay of a display, another battery that is included in another battery bay of the display may be operable.

### Battery Optimization: Internal Batteries and Insertable Batteries

In a related embodiment, display 120 includes one or more internal, rechargeable batteries that are separate from one or more hot swappable batteries. The one or more internal, rechargeable batteries might not be easily removable from display 120. Instead, such batteries may have a relatively long battery life, such that they may be recharged multiple times without significant degradation in how long a full charge can power one or more functions of display 120.

In this internal battery embodiment, one or more hot swappable batteries may charge (a) the one or more internal batteries, (b) power display 120 (e.g., in presenting content on the screen of display 120) or (c) both at the same time.

In an embodiment, display 120 (and/or base station 110) includes a battery discharge component that determines which batteries to use to power one or more functions of display 120. The battery discharge component may be implemented in software, hardware, or any combination of software and hardware. Functions of display 120 include presenting content on a screen of display 120, playing audio through one or more speakers of display 120, capturing digital images using a camera of display 120, capturing audio using a microphone of display 120, reporting status data of display 120 (and/or one or more components therein) to base station 110, receiving instructions from base station 110, using one or more sensors (such as pressure sensors, magnet sensors, proximity sensors, etc.), and attaching display 120 to a vertical surface (e.g., using vacuum technology or adhesives).

In this embodiment, display 120 includes multiple insertable (e.g., hot swappable) batteries and one or more internal batteries. An insertable battery may power one or more functions of display 120, charge one or more of the one or more internal batteries, or both. If no insertable battery is inserted into display 120, then the functions of display 120 may still be powered by the one or more internal batteries.

The battery discharge component may be implemented in display 120, in base station 120, or a combination of two. The battery discharge component chooses which insertable battery to use to charge an internal battery or to power a function of display 120 based on the current charge of each insertable battery and optionally, the charge of the one or more internal batteries.

As described in more detail herein, a factor in selecting which insertable battery to use is which insertable battery is blocked. For example, a blocked battery (or one that is difficult to remove and replace) may be discharged last.

In an embodiment, the battery discharge component considers the health of a battery in determining whether to use the battery or another battery. For example, if the health of a battery is not good, then data is stored that indicates the health. Also, the battery discharge component determines to not use that battery as much as other batteries. Health of a battery may be determined based on how fast the battery's charge depletes when the battery is not in use and/or when the battery is in use.

In an embodiment, if the battery discharge component determines that all insertable batteries have the same charge (and, optionally, are considered “healthy”), then the battery discharge component determines to discharge the insertable batteries equally in a round robin fashion. For example, the battery discharge component determines that insertable battery A is to be used (e.g., to power display 120 or to charge one or more internal batteries) from 100% charge to 80% charge, then determines that insertable battery B is to be used (e.g., to power display 120) from 100% charge to 80% charge, and so forth for each insertable battery. After each insertable battery is discharged to 80%, then the battery discharge component determines that battery A is to be used from 80% charge to 60% charge, then determines that battery B is to be used from 80% charge to 60% charge and so forth.

In an embodiment, if the battery discharge component determines that different insertable batteries have different charges, then the battery discharge component identifies the insertable battery with the highest charge and uses that insertable battery (e.g., to power display 120 or to charge one or more internal batteries) until its charge matches an insertable battery with a lower charge, such as the insertable battery that currently has the lowest charge among the insertable batteries. Such a discharge technique minimizes the weight differential between the multiple insertable batteries. Having insertable batteries that are equal in weight ensures that display 120 is balanced.

In an embodiment, the battery discharge component implements a default discharge algorithm that is customizable. For example, a user of display 120 provides input (e.g., through voice command via a microphone of display 120, controls on a touchscreen of display 120, or through an application executing on the user's personal device) that modifies the default discharge algorithm. The modified discharge algorithm is a custom discharge algorithm.

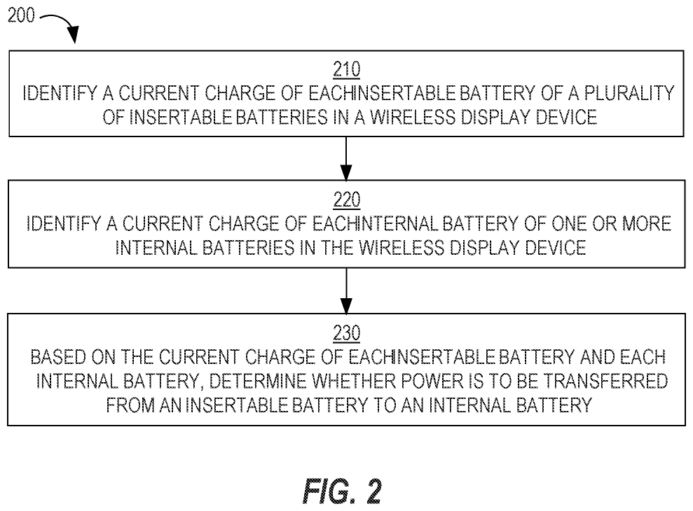

FIG. 2 is a flow diagram that depicts an example process 200 for optimizing battery usage in a wireless display device, in an embodiment. Process 200 may be performed by the wireless display device (e.g., display 120), base station 110, or a combination of the two computing devices.

At block 210, for each insertable battery of a plurality of insertable batteries in a wireless display device, a current charge of each insertable battery is identified. Block 210 may involve the display device transmitting the charge data that indicates the current charge to base station 110.

At block 220, for each internal battery of one or more internal batteries in the wireless display device, a current charge of each internal battery is identified. Block 220 may involve the display device transmitting the charge data that indicates the current charge to base station 110.

At block 230, based on the current charge of each insertable battery and each internal battery, it is determined whether power is to be transferred from an insertable battery of the plurality of insertable batteries to an internal battery of the plurality of internal batteries. Block 230 may be performed by base station 110. Thereafter, base station 110 transmits instructions to the display device regarding which batteries (if any) are to transfer charge or power to other batteries.

### Battery Optimization: Blocking

In an embodiment where there are multiple batteries that may be inserted into a single display, when the display is in use, batteries are discharged in a particular order based on where the batteries are located relative to one or more other objects external to the display and/or based on a current charge of each battery.

In an embodiment, a communication system enables an automatic determination of the location of a display's batteries such that optimization and location of the batteries lengthens the display time of the display. Each display may include a battery network that is controllable by base station 110 (or a component of the display) that determines which batteries are more easily removed based on a priori knowledge of the location either by user input or by sensors detecting location of the display relative to a determined network location.

For example, in an embodiment, base station 110 receives an outline or space location of each display relative to walls, rooms and the like. Thus, base station 110 has an electronic map of an area (e.g., an office, a home, a restaurant) and stores display location data that identifies a specific location on the electronic map. Base station 110 may even include base station location data that identifies a specific location on the electronic map. A display may be moved from one location within the area to another location within the area. Each display may include a location identification system, such as a Global Positioning System (GPS) locator, that transmits a signal to base station 110, the signal indicating a location of the display, after which base station 110 updates its display location data.

In a related embodiment, proximity location sensors at predefined locations on the perimeter of the display employ object detection technology for determining a distance (e.g., in centimeters or inches) between the sensor (or edge of the display) and an object that is external to the display. Examples of objects that may be adjacent to a display include a cabinet, a wall, a hanging picture, and a wall ornament. Examples of object detection technology include echolocation technology and optical sensing technology. The technology may periodically transmit a signal and receive a response (or “bounce”) signal. The technology calculates a distance to a detected adjacent object based on a time between transmission of the original signal and receipt of the response signal.

In either the map embodiment or the proximity location sensor embodiment, for each battery bay, it is determined whether a battery may be ejected from that battery bay and a new battery inserted into that battery bay. This determination may be performed by base station 110 or a component of the display on which the battery is located. A length of each battery may be a default value, such as four inches. If an object that is adjacent to a battery bay is less than the length of a battery plus an optional additional length (e.g., one inch) for convenience in replacing batteries, then it is determined that the battery in the battery bay is “blocked.” A “blocked” battery may be unblocked by moving the display (or moving the object), but it may be inconvenient to do so. A “blocked” battery may still be replaced without moving the display (or the adjacent object); however, replacing such a battery may be inconvenient for a user of the display due to the small distance between the display and the adjacent object.

In an embodiment, in response to detecting one or more blocked batteries of a display and detecting one or more unblocked batteries of the display, a battery optimizer implements a particular discharge technique that accounts for the blocked batteries. The battery optimizer may execute within base station 110 or within the display in question. (A battery optimizer may be implemented in hardware, software, or any combination of hardware and software.) In one discharge technique, unblocked batteries are used first while the display is in use (e.g., displaying streaming content from a base station). Only after the unblocked batteries are depleted (or at a particular charge percentage, such as 10%, or at a remaining estimated discharge time, such as thirty minutes) are the blocked batteries discharged. Such a discharge technique allows the blocked batteries to be replaced last, while the unblocked batteries (which are easier to be accessed for the user) are replaced first. In fact, a user may choose to keep replacing only unblocked batteries, in which case blocked batteries may maintain a certain level of charge for a significant amount of time, such as months, without being used to power the display.

In a related embodiment, factors other than blocked status of two or more batteries of a display that influence which batteries to use first in operating the display include the battery with the most available power, the age of each battery, and the lifetime expectancy of each battery. For example, an unblocked battery with the least available power may be used solely so that that battery may be replaced sooner. If all unblocked batteries became depleted at the same time, the user might not have enough warning to replace all those batteries at the same time. As a similar example, the unblocked battery with the least lifetime expectancy may be used solely so that that battery may be replaced sooner.

In an embodiment, one or more notifications are generated when a battery's charge is depleted (or soon to be depleted), signaling to a user to replace that battery. Types of notifications include an audible sound produced by the display, an audible sound produced by base station 110, a light on the display (e.g., where each battery bay includes a separate light), a text message sent to a phone of a user of the display, an application message sent to an application installed on the user's personal (e.g., smartphone) device, an email message sent to an email account of the user. A notification may repeat, such as every second, minute, hour, etc. Different types of notifications may have different repeat schedules. A notification may be more frequent as full depletion approaches. Additionally, different combinations of notifications may be employed based on the time before battery charge depletion and/or full depletion of all batteries of a display. For example, a text notification is sent for each battery that is depleted, as long as there is at least one battery that is not close to depletion (e.g., one week's worth of display life based on current usage characteristics). Then, an audible sound is made when there is only one battery left that is not fully discharged. The type and/or frequency of notifications may also depend on whether the remaining battery (or batteries) (i.e., that hold a charge) are blocked or not. For example, if the sole remaining battery is blocked, then audible notifications are used rather than text or application messages.

In an embodiment, a particular display wirelessly charges one or more displays that are adjacent (or touching) the particular display using one or more batteries within the particular display. This is referred to as “power sharing.” Power sharing may be useful if the one or more displays have one or more blocked batteries. Thus, one or more unblocked batteries of one display may be used to charge one or more blocked batteries of an adjacent display. In some situations, multiple batteries or all batteries of a display are blocked. For example, a particular display may be surrounded by four displays, each surrounding display touching a different edge of the particular (or center) display. The center display essentially pulls charge from surrounding displays. In other words, each surrounding display potentially shares its remaining battery power with the center display. In this way, a user is not required to replace any of the blocked batteries in the center display.

In an embodiment involving power sharing, each display communicates battery data, comprising multiple items of information, to base station 110. (Alternatively, battery data is shared among multiple displays that are connected for power sharing purposes and the displays collectively determine how to discharge their respective batteries, or one of the displays makes the decision and provides discharge instructions to the other connected displays.) Examples of battery data transmitted from a display include the current charge of each battery of the display, an age of the battery, a health of the battery, a number of times the battery has been charged, a block/unblock status of each battery, and a connection status of the display indicating whether the display is connected to an adjacent display such that the connection allows power sharing. Battery data from a particular display may include an identity of the particular display and the identity of each display that is able to power share with the particular display. In this embodiment, base station 110 includes a battery optimizer that receives battery data from multiple displays and controls when batteries of which displays will be discharged. For example, if power sharing is possible, then the battery optimizer may instruct a first display with one or more unblocked batteries to power share with a second display with one or more block batteries. In an embodiment where a battery optimizer is implemented in each display, then a battery optimizer of a first display communicates with a battery optimizer of a second display (with which the first display can power share) in order to determine which display will act as a power coordinator. For example, the display with the fewest unblocked batteries becomes the power coordinator and sends instructions to adjacent, power sharing displays to control power sharing among those displays.

In an embodiment, a display with one or more blocked batteries, such as a centrally-located display (i.e., surrounded by displays on all sides), implement a mechanical solution such that the display responds to a mechanical push, resulting in a movement of the display enabling removal of one or more batteries, either on one side or the entire display in accordance with system requirements. The mechanical push may be in the center of the display or on both sides of the display, such that both sides need to be pushed to activate the mechanical solution. For example, a swinging system may be implemented that enables just enough movement on one side of the display to insert and/or remove batteries. As another example, upon activation of the mechanical solution, the display moves away from (or perpendicular to) the surface to which the display is attached or is touching, giving enough space for the previously-blocked battery to be removed and replaced with another battery.

Another embodiment is directed to hydrogen fuel cells. For example, instead of using rechargeable lithium battery, displays are powered by hydrogen fuel cells. A hydrogen fuel cell is contained with a canister that fits within a slot (or power bay) of a display. Thus, in one or more embodiments, rather than lithium ion or polymer batteries, canisters are used and operable for up to six months. Replacing canisters displaces the need for recharging batteries. Instead, canisters can be recharged and reused, benefiting the environment. In both a lithium-based battery and hydrogen fuel cell embodiment, each display may be below 20 lbs. per 55-inch display.

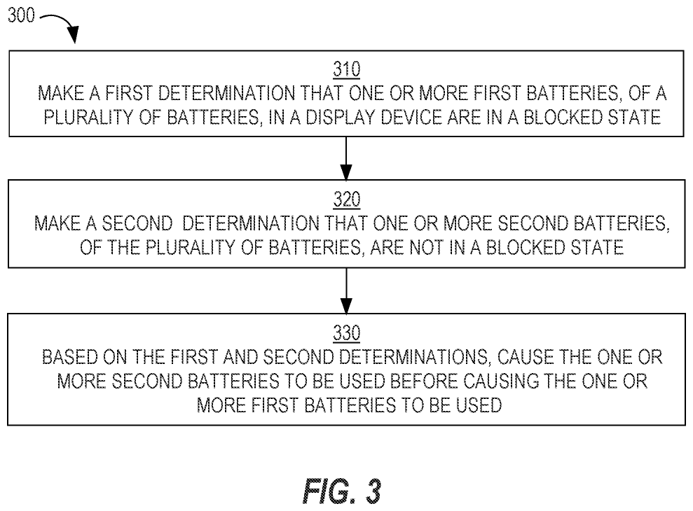

FIG. 3 is a flow diagram that depicts an example process 300 for optimizing battery usage, in an embodiment. Process 300 may be performed by base station 110, display 120, or a combination of the two.

At block 310, a first determination is made that one or more first batteries, of a plurality of batteries, in a display device are in a blocked state. This determination may be made based on one or more sensors in the display device that detect that the display device is connected to another display device or that the display device is located near some external object that may be blocking access to the one or more first batteries. Block 310 may involve the display device transmitting this blocked status to base station 110.

At block 320, a second determination is made that one or more second batteries, of the plurality of batteries, are in an unblocked state. This determination may also be made based on one or more sensors in the display device, which sensors may be different than the one or more senses that are used to detect that the one or more first batteries are in the blocked state. Again, block 320 may involve the display device transmitting this non-blocked status to base station 110.

At block 330, based on the first determination and the second determination, the one or more second batteries are caused to be used (e.g., to power one or more functions of the display device or to charge internal batteries of the display device) before the one or more first batteries are caused to be used for power. Additionally or alternatively, at least one of the one or more second batteries is caused to transfer electrical power to at least one of the one or more first batteries. This is referred to as power swapping. Block 330 may involve the display device transmitting this blocked status to base station 110.

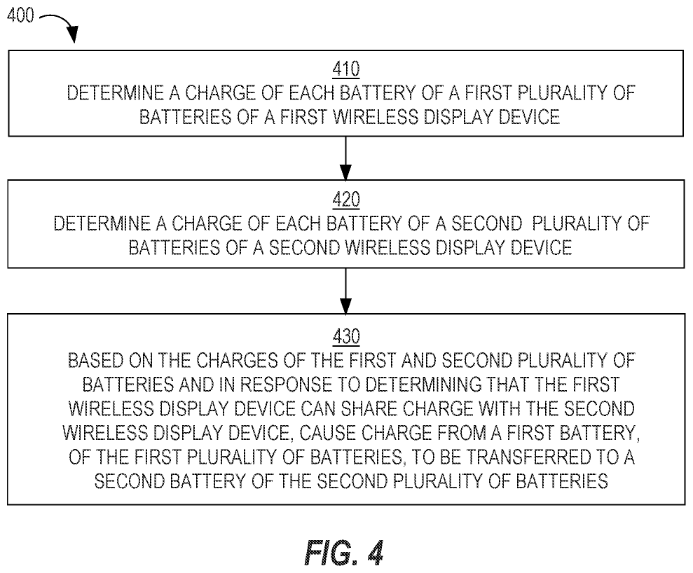

FIG. 4 is a flow diagram that depicts an example process 400 for optimizing battery usage among multiple display devices, in an embodiment. Process 400 may be performed by base station 110, display 120, or a combination of the two.

At block 410, a charge of each battery of a first plurality of batteries of a first wireless display device is determined.

At block 420, a charge of each battery of a second plurality of batteries of a second wireless display device that is separate from the first wireless display device is determined.

At block 430, based on the charges of the first and second plurality of batteries and in response to determining that the first wireless display device can share charge with the second wireless display device, charge from a first battery, of the first plurality of batteries, is transferred to a second battery of the second plurality of batteries.

Block 430 may determine that batteries in the second wireless display device are almost drained of charge and that one or more of them need more charge to keep the second wireless display device attached to a vertical surface.

Block 430 may also determine that one or more batteries in the second wireless display device and one or more batteries in the first wireless display device are blocked and that charge from unblocked batteries should be transferred to the blocked batteries. In this way, the unblocked batteries discharge (or drain) faster and may be replaced fasted.

### Display-to-Surface Adhesion Techniques

Without any wires to power a display or to transmit content to the display, the display may be moved and placed virtually anywhere in a physical environment, such as a home, office, or other venue. However, current techniques for mounting a display on a surface (e.g., a wall or ceiling, for which there tends to be ample space) are laborious and often require holes in the surface, which holes need to be covered or filled in (or otherwise fixed) if/when the display is moved. Such mounting is done with the intention that the display (or television) will not move for a significant amount of time. Also, such mounting is done with the expectation that there is an electrical outlet nearby and that there a sufficiently long power cord from the television to that electrical outlet.

On the other hand, techniques for standing a display on a desk or other horizontal surface require such a surface, which may be difficult to find in many situations. The difficulty may be due to the size of the display; the wider the display, the wider the surface on which to place the display. Also, existing horizontal surfaces in a home or office tend to already be used for other purposes, such as holding lamps, storing books, or displaying decorative items.

In an embodiment, one or more adhesion (or attachment) techniques are implemented to secure (or attach) a display to a vertical surface (e.g., a wall), without requiring (a) making any holes or (b) traditional mounting involving screws, bolts, etc. Example adhesion techniques include vacuum suction and one or more types of adhesives. While embodiments are described in the context of vertical surfaces, such as walls, windows, and doors, embodiments are not so limited. A display may adhere to any flat surface, whether vertical, somewhat vertical (e.g., 30% from vertical), or horizontal, such as a ceiling or a floor.

### Vacuum Adhesion Techniques

In a vacuum suction embodiment, a display includes one or more vacuum suction devices that are integrated in a display. Each vacuum suction device implements vacuum technology that enables the display to adhere to one or more surfaces, such as glass, acrylic, or drywall.

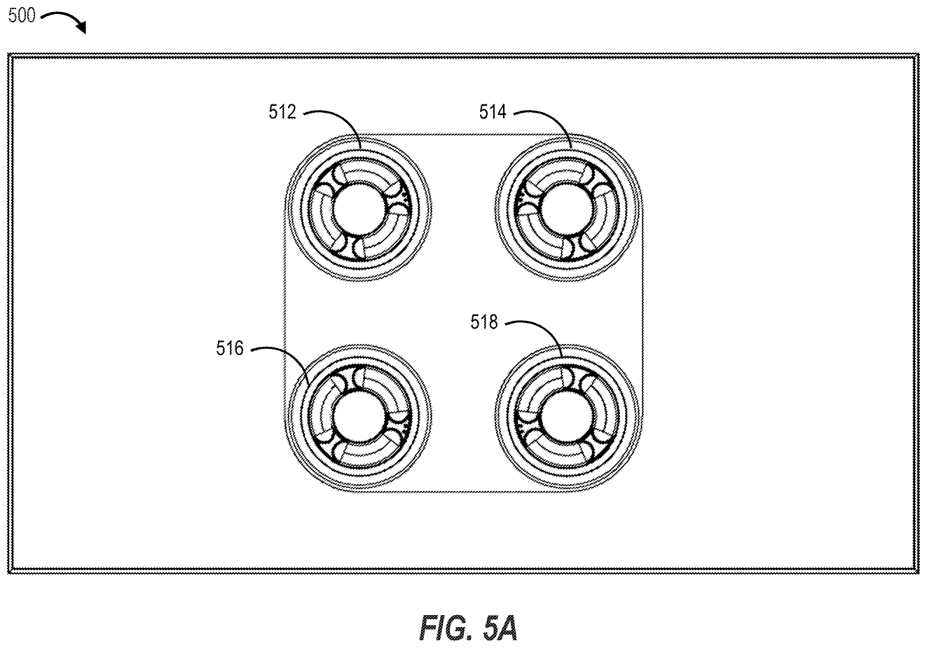

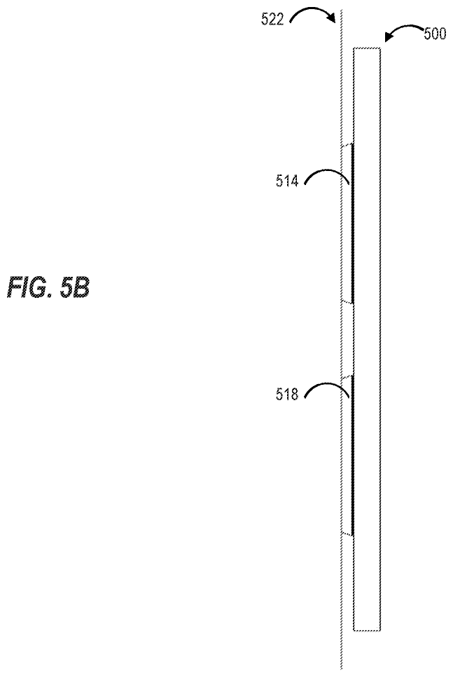

FIGS. 5A-5B are diagrams that depict a non-screen side of an example display 500 that implements a vacuum mechanism, in an embodiment. In this example, the non-screen side includes four suction cups 512-518, each corresponding to a different vacuum suction device. FIG. 5B depicts display 500 from a side view. This side view depicts two of the suction cups in contact with a vertical surface 522.

Each vacuum suction device includes one or more suction areas (including a suction surface), one or more pumps per suction area, and a pressure sensor for each suction area. Each suction area comprises, on the edges, suction material that is designed to be placed on a vertical surface, is secured to the display, and forms a closed shape, such as a circle or rounded rectangle. The suction material surrounds the inner suction area. Each pump may be activated to create a vacuum within a volume of space adjacent to the corresponding suction area as the suction material is pressed against a vertical surface.

A pump may be activated in one or more ways. For example, one or more sensors in the display detects a distance between the sensors and a vertical surface. If the distance is less than a threshold number (e.g., one inch), then the corresponding pump is activated. Another factor that may be necessary when activating a pump is whether the display is positioned vertically. As another example, a user holding a display may press a button (e.g., on one of the sides of the display) that activates the pump. The button may be placed in a location where a user would likely hold the display while placing the display against a vertical surface. As another example, a user holding a device may provide an audible command (e.g., “Stick to wall”) that a voice recognition component in the display recognizes and, in response, causes the pump to activate. As another example, two or more of these ways to activate a pump may be required to trigger activation of the pump.

In an embodiment, one or more pumping indications are generated to signal to a user that the pump is working. Pumping indications inform the user to not let go of the display yet, until the display is finally secure, which may be indicated by another indication. Pump indications may be audible, visual, and/or physical or haptic. For example, a pump makes an audible sound while pumping air out of a suctioned cup. As another example, the display plays a sound (through one or more audio speakers of the display; such as a sound that mimics or amplifies the actual pump sound while in operation) and/or informs the user that the pump is operating and that the user should remain holding the display. As another example, a border of the display vibrates or shakes (e.g., slightly) while the pump is operating. As another example, the display causes the screen to display a message informing the user that the pump is operating and that the user should remain holding the display. When the pump is finished pumping, then the pumping indications, whether visual, audible, or haptic may cease and be replaced with a “finish” indication that the display is securely attached to the vertical surface. A finish indication may be visual, audible, and/or haptic. For example, for hearing impaired individuals, a visual message on a screen of the display indicates that the display successfully attached to the vertical surface.

In an embodiment, a pressure sensor of a vacuum suction device detects a pressure of the corresponding vacuum that the corresponding pump created. If the pressure is under a threshold pressure, then the pump continues to pump out air from the suction area. If the pressure matches the threshold pressure, then the pump ceases. The threshold pressure may depend on the weight of the display. The higher the weight, the higher the threshold pressure. The pressure sensor may continually sense pressure of the corresponding vacuum and activate a pump whenever the pressure falls below the threshold pressure.

In a related embodiment, each suction device is associated with two pumps. A first pump removes more air per each pump action compared to a second pump. The first pump may be used to attach a display to a vertical surface while the second pump is used to keep the display attached to the vertical surface. For example, over time, air may escape or the pressure inside the suction cup otherwise decreases. In response to the pressure sensor detecting that a vacuum's pressure is below a threshold pressure, the second pump is activated to maintain the pressure at or above the threshold pressure. The second pump may be quieter (and, thus, less noticeable) than the first pump. This ensures that there is minimum audible disruption in the user's viewing experience while the display is in use. Thus, the first (potentially larger) pump in combination with the second (potentially smaller) pump maintains the suction connection of a display to a surface.

In a related embodiment, when a display is currently not in use (e.g., the display is turned off or the display does not detect a person watching the display), the display activates the first pump in response to the pressure sensor for the corresponding vacuum detecting that the pressure of the corresponding vacuum is below a pressure threshold. The first pump may be louder and may be more effective and/or efficient relative to the second pump, such as more efficient in battery usage. Therefore, the first pump is preferable, except when the display is in use.

Some types of surfaces may be easier to adhere to using vacuum suction devices than other types. This is because different surfaces are associated with different leakage rates, or the rate at which pressure of a vacuum decreases. The following are examples of different types of surfaces, in descending order of leakage rates: glass, acrylic painted walls, latex painted walls, drywall, cement, and brick.

In an embodiment, depending on the type of surface that is being used for the suction pumps, a different pressure level is maintained. For example, for a glass surface, a first pressure level is maintained, but for a drywall surface, a second, higher pressure level is maintained because there is more pressure leakage from drywall surfaces than glass surfaces. However, constant pumping, which requires a significant amount of power, affects battery life. In an embodiment, the type of connection or surface, for example, whether it is a leaky connection or a brick wall, is taken into account in determining battery life and a user interface is updated (whether on a screen of the display or on a screen of a smartphone through an application installed thereon) to indicate that an alternate location or surface may be desirable. For example, if a surface is porous, a predicted battery life may be highly limited causing an alert to be sent and presented on a smartphone, a screen of display 120, or other user interface wirelessly coupled to base station 110, which receives input data from display 120. The alert may also be presented on display 120, all displays wirelessly connected to base station 110, as an audible warning, or as a message received on a smartphone as a text message or app notification.

In a related embodiment, based on a current battery life of display 120, base station 110 determines that attaching display 120 to a vertical surface is not prudent and transmits a message/notification informing a user of display 120. The message may recommend that one or more batteries in display 120 should be charged before activating a vacuum mechanism of display 120. The determination may also be based on the type of surface to which the user is attempting to attach display 120. Thus, for some surfaces (e.g., porous surfaces), the battery charge/life must be high, while for other surfaces (e.g., glass), the battery charge may be low and still acceptable for activating the vacuum mechanism.

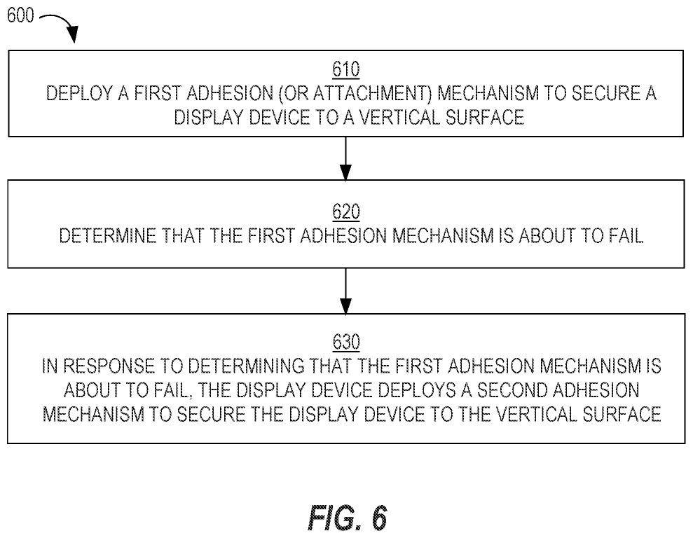

FIG. 6 is a flow diagram that depicts an example process 600 for a wireless display device deploying multiple adhesion (or attachment) mechanisms, in an embodiment.

At block 610, a first adhesion mechanism is deployed by display device to secure the display device to a vertical surface. The first adhesion mechanism may be a vacuum mechanism or a non-intrusive adhesive, such as “gecko glue.” The first adhesion mechanism may be deployed in response to user input and/or a detection that the display device is touching or in close proximity to the vertical surface, such as less than one inch.

At block 620, it is determined that the first adhesion mechanism is about to fail. Block 620 may involve determining that the battery life of the display device (or of all batteries in the display device) is about to cease. In other words, the battery charge is close to being fully depleted.

At block 630, in response to determining that the first adhesion mechanism is about to fail, the display device deploys a second adhesion mechanism to secure the display device to the vertical surface. The second adhesion mechanism is different than the first adhesion mechanism. For example, deploying the second adhesion mechanism may involve applying industrial tape.

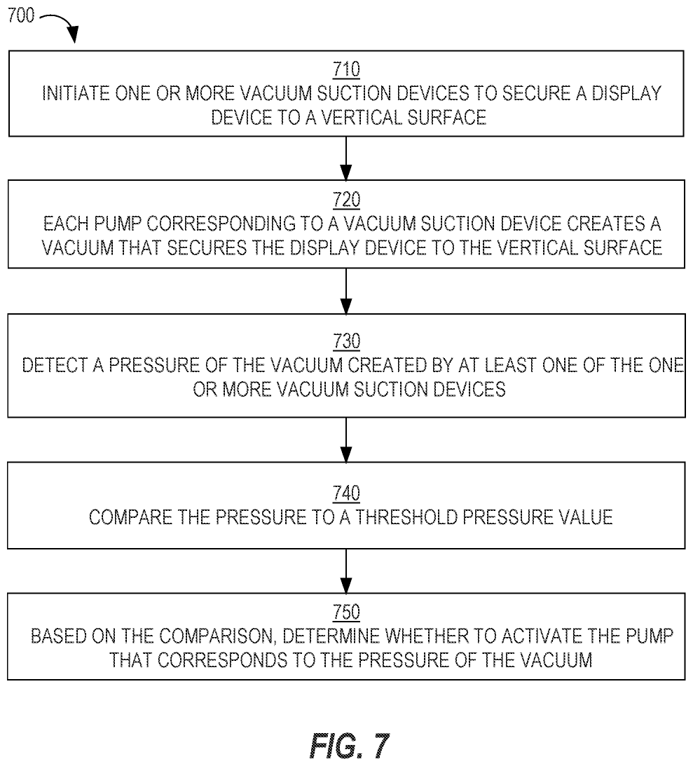

FIG. 7 is a flow diagram that depicts an example process 700 for a wireless display device deploying a vacuum mechanism, in an embodiment.

At block 710, a display device initiates one or more vacuum suction devices to secure the display device to a vertical surface. Block 710 may be preceded based on an instruction from base station 110 to the display device to deploy the vacuum mechanism. Alternatively, block 710 may be performed in response to display device detecting the proximity of the display device to the vertical surface and/or based on user input, such as selecting a vacuum activation button on the display device.

At block 720, the pump of each of the one or more vacuum suction devices creates a vacuum that secures the display device to the vertical surface. Each pump pumps out air from a volume created based on a part of the corresponding suction device and the vertical surface.

At block 730, a pressure sensor in the display device detects a pressure of the vacuum created by one of the one or more vacuum suction devices. Power to the pressure sensor may cease when the vacuum mechanism is not activated or deployed. This can conserve battery power.

At block 740, a comparison between the pressure and a threshold pressure value is performed. Block 740 may be performed by the display device or by base station 110, which receives, from the display device, pressure data indicating a current pressure reading. The display device may send pressure data periodically, such as every second or few seconds.

At block 750, based on the comparison, it is determined whether to activate the pump that corresponds to the pressure of the vacuum. For example, if the current pressure is less than the threshold pressure value, then the pump is activated. Otherwise, the pump is not activated.

### Example Implementation of a Vacuum Suction Device

In an embodiment, a vacuum suction device includes a suction cup that comprises four main sections. The body of the suction cup may be made from a rigid plastic. The suction cup side (i.e., facing the vertical surface to which the display is to attach) comprises an outer ring, an inner ring, a segmented region, and a center region. For example, the outer ring may be made of conformable foam that seals air on multiple surfaces, such as surfaces ranging from glass to textured drywall. The inner ring (just inside the outer ring) may be made of a rubber-like material that, when pressed by the force of suction to the vertical surface, creates a strong static friction force that lifts the weight of the display. The segmented region may comprise three segments that are air pockets (e.g., made of plastic) that create a permanent volume of air inside the cup. This permanent volume of air gives the suction cup time before the suction cup releases suction completely. The center region may be another rubber pad providing additional lifting force.

In a related embodiment, a suction cup comprises two small ports: one port connecting to pneumatic devices including a pump, check valve, release valve, and filters, and the other port connecting to a pressure sensor.

In a related embodiment, a vacuum suction device includes a low-profile tilting mechanism that allows the suction cup to tilt a few degrees to conform to semi-curved surfaces, such as a curved refrigerator or warped drywall. The tilting mechanism is on the opposite side from the suction cup.

### Leveling

In an embodiment, a display includes a leveling indicator. The leveling indicator provides a visual, audible, and/or haptic feedback to a user to indicate whether a display is level prior to attaching the display to a vertical surface. For example, an audible indicator informs a user that a display should be tilted more to the left or the right, depending on the current level of the top of the display. As another example, one side of the display (i.e., the right side or the left side) vibrates indicating that that side needs to rise vertically relative to the other side of the display.

As another example, a digital level is presented on a screen of the display when the display detects that the user is attempting to attach the display on a vertical surface. (Such detection may include detecting that one or more locations on the back of the display are within a certain distance of a vertical surface.) The digital level is based on input from one or more accelerometers that are integrated within the display. The accelerometers provide a measurement of how level a top of a display is. Because a display may be rectangular and may be attached to a vertical surface in a landscape mode or portrait mode, the accelerometers detect which edge of the display is the top and measure the levelness of that edge with respect to the horizontal/ground.

In a related embodiment, a pump of a suction device is activated in response to detecting that the top of a display is level or is near level, such as within a few degrees. The activation may be triggered after detecting that the top of the display is level after a certain period of time, such as a half second, one second, or 1.5 seconds.

In a related embodiment, a display includes a leveling system that comprises multiple suction cups that enable auto-leveling, if a user so desires. For example, three or four suction devices may include servos that enable slight movement of the display in any direction or a particular direction. In another embodiment, one or more suction devices in a center of the rear of the display may be equipped to move the display by servos or by directional devices that may direct the display in different directions. The leveling system may be overridden either via a user interface on a mobile device, directly on the display, via facial recognition, gestures or via an interface connected to the base station.

### Additional Adhesion Techniques

Adhesives are an alternative way to adhere (or stick) a display to a vertical surface. Some adhesives are relatively easy to undo without leaving a portion of the adhesive on a vertical surface, while other adhesives leave a portion of the adhesive on a vertical surface when removing the display from the vertical surface. For example, some industrial strength adhesives may result in removing paint (where the adhesive was touching) from a painted wall when removing the display from the painted wall.

In an embodiment, adhesives are considered a secondary mechanism to adhering a display to a vertical surface. In this embodiment, an adhesive is deployed from a display while the display is adhering to a vertical surface using vacuum technology. A secondary adhesion mechanism is useful if the pressure in a vacuum created by a pump on the display is losing pressure and the pump is unable to maintain the pressure above a threshold pressure value. Such inability may be the result of the pump ceasing to function, the pump not being able to maintain the threshold pressure, or due to insufficient battery power to run the pump.

In an embodiment, a display automatically deploys or activates a secondary adhesion mechanism upon detection of one or more conditions. One deployment condition is the immanency of a vacuum failure of one or more vacuums maintained by the display. Immanency of a vacuum failure may be calculated based on the total remaining battery life (e.g., in minutes) of one or more batteries in the device and/or a pressure leakage rate. (Pressure leakage rate may be calculated at least based on two pressure measurements and a timestamp between the two pressure measures. Pressure leakage rate may change over time.) The greater the pressure leakage rate of a vacuum, the sooner the vacuum failure. Similarly, the lower the total remaining battery life, the sooner the vacuum failure. An amount of power to maintain a threshold pressure value (e.g., watts/hour) may be calculated based on a current leakage rate.

Another secondary adhesion mechanism deployment condition is a detection of a type of vertical surface. For example, a display includes one or more sensors that detect a type of vertical surface. A sensor may detect a porous surface based on a pressure leakage rate, even though one or more batteries powering the display are fully charged. A sensor may directly detect that a vertical surface is brick or drywall, for example. If the sensor detects a certain type of surface from a list of one or more types of surfaces, then a secondary adhesion mechanism is deployed.

In an embodiment, a display is capable of deploying one of multiple types of adhesives. Some adhesives may be less likely to leave a mark on a surface, less likely to damage the surface when removed, easier to remove, and/or easier reuse. Other adhesives, on the other hand, may be more likely to leave a mark on the surface, more likely to damage the surface when removed, harder to remove, and/or harder to reuse. Such latter adhesives may be industrial grade adhesives that are only deployed when determined to be necessary to prevent the display from falling and potentially damaging the display and/or coming into contact with an object that is immediately below the display.

In an embodiment, a display deploys multiple types of adhesives, whether sequentially or concurrently. For example, a displays deploys a first adhesive and, after determining that the first adhesive is not effective, deploys a second adhesive. The first adhesive may be easier to remove than the second adhesive and less likely to damage the surface than the second adhesive.

In a related embodiment, one or more sensors in a display determine which of multiple types of adhesives is the most appropriate to deploy given the type of surface. Some adhesives are more appropriate for a particular type of surface than other adhesives. Thus, a display (or base station 110) maintains a mapping between adhesive types and surface types.

In a related embodiment, a display deploys a least intrusive adhesive (e.g., “gecko glue”) before determining to deploy a most intrusive adhesive (e.g., industrial grade tape). After deploying the first adhesive, the display detects whether the first adhesive can stick to the surface based on the force. Some less intrusive adhesives do not attach well to certain surfaces, such as drywall, painted wall, and brick.

In an embodiment, a display includes a heat source that is capable of removing one or more types of adhesives, even industrial adhesives that are known to be difficult to remove when attached to a surface. The heat source may be activated as soon as the display detects that there is sufficient battery power attached to the display, whether directly in one or more of the displays battery bays, or in one or more batteries that are external to the display but are electrically connected, allowed the external batteries to transfer power to one or more of the display's batteries. Additionally or alternatively, the heat source is activated when a vacuum (attaching the device to the surface) is successfully created.

### Release Technology

From time to time, a user of a (wireless) display may wish to move the display from one surface to another. In an embodiment, a display includes one or more release mechanisms to enable a user to release the display from a surface to which the display is currently attached. If a display includes multiple adhesion mechanisms (e.g., vacuum and adhesive, such as industrial tape), then the display includes multiple release mechanisms.

In an embodiment, a release mechanism includes a verification component. The verification component verifies that a user wishes to release the current adhesion mechanism in use. If a display includes multiple release mechanisms, then each release mechanism may be communicatively coupled to the verification component. A verification component may include an audio verification component, a visual verification component, and/or a touch verification component. A touch verification component may include sensors on one or more sides of the display that, when detecting a hand or fingers of a user, causes one or more release mechanisms to be activated. Touch verification may even include fingerprint verification that verifies whether a fingerprint of a user touching one or more sensors on the display matches a fingerprint of an authorized user of the display. Fingerprint verification may be performed by the display or by base station 110. If the latter, the display transmits fingerprint data (generated by the display) to base station 110, which stores one or more fingerprint data items of one or more authorized users. If base station 110 detects a match, then base station 110 sends a verification response to the display indicating that the user touching the display is authorized to release the display from the surface, triggering one or more release mechanisms.

A visual verification component comprises a camera on the display taking a digital image of a user that is facing the display and the display (or base station 110) verifying that the user is an authorized user to move the display. The camera may be embedded in the display such that the camera does not need to move in order to take the digital image. Alternatively, the camera may initially not be visible (to a user that is facing the screen of the display) while the camera is in its “resting” or default position in the display. Then, upon detecting that visual verification is to be performed, the camera moves from the initial position and becomes visible to the user. The camera may “pop” out in response to a user pushing down on the camera, activating a camera release mechanism. Alternatively, the user may select a button (on the display) that is next to a side of the camera. The camera may have multiple uses, such as facial recognition for authorizing certain actions, gesture recognition when issuing commands, and virtual reality.

If the user detected in the digital image does not match a base image of an authorized user, then no release mechanism is activated. If base station 110 performs visual verification, then the display may transmit the digital image to base station 110, which stores one or more base images of an authorized user (or characteristics extracted from the one or more base images), and base station 110 compares the digital image (or characteristics extracted therefrom) with the one or more base images (or characteristics extracted therefrom). Base station 110 transmits a verification response to the display, indicating whether the user is authorized to release the display from the surface.

An audio verification component comprises a microphone on a display receiving audio input from the user and detecting whether digital audio data generated based on the audio input) matches a voice signature of an authorized user. If so, then one or more release mechanisms on the display are activated; otherwise, the one or more release mechanisms are not activated. The audio input may require certain words or phrases spoke, such as “Release display from the wall.” Audio verification may be performed entirely by the display, meaning that the display stores one or more voice signatures of one or more authorized users. Alternatively, audio verification involves the display sending digital audio data (that a microphone generates based on a voice command from a user) to base station 110 that stores one or more voice signatures of one or more authorized users. Base station 110 then compares the digital audio data with one or more voice signatures and, if a match is detected (e.g., a 90% match), then base station 110 transmits a verification response to the display.

In an embodiment, a determination is made regarding whether enough battery power/charge is present to allow a release from a surface and/or to allow vacuum adhesion to another surface. This determination may be performed by the display in question or base station 110. Some release mechanisms may require battery power to function. If insufficient battery power is present (or the charge is lower than a threshold charge), then a release is denied. Otherwise, a release is granted.

A release mechanism for a vacuum suction device may be to pump air into a vacuum or to create an opening in a suction cup area to allow air into the vacuum.

A release mechanism for an adhesive (e.g., tape or glue) is a heating element (and optional fan) that directs heat to the adhesive that has been deployed. Heat breaks down bonds between the adhesive and the surface to which the adhesive is attached. Another release mechanism for an adhesive is spraying a solvent, such as ethyl acetate, which breaks down bonds between the adhesive and the surface.

In an embodiment, if it is determined that an adhesive (e.g., tape) is not be removed from a surface using a release mechanism, then the display will release the adhesive while the adhesive remains on the surface. If such a circumstance occurs, then instructions for removing the adhesive from the surface may be distributed, such as being presented on the display or other displays, or as a notification through a text message, app message, or email message.

If a display is attached to a surface using multiple adhesion mechanisms and a release is granted, then multiple release mechanisms are implemented, one for each adhesion mechanism.

### Self-Lowering Technology

In a rare instance, a display might fall from a surface despite one or more adhesion mechanism being in place. For example, an earthquake might provide enough force to dislodge a vacuum suction or industrial strength tape.

In an embodiment, a display and/or base station 110 implements a warning system. The warning system, when activated, may use visual and audio indications to warn one or more users that a fall of the display is imminent. Example visual indications include one or more warning messages that are transmitted to a user, in the form of text messages, app messages, and/or email messages. Another example, visual indication includes a warning message that is presented on a screen of the display and/or a screen of each of one or more other displays that are also communicatively coupled to base station 110. For example, all displays that are communicatively coupled to base station 110 present a warning, whether audible, visual, or both. An example of an audio indication is an audio warning transmitted through a speaker of the display and/or a speaker of one or more other displays that are also communicatively coupled to base station 110.

In an embodiment, a display is protected by automatically deploying airbags from all corners of the display and the airbags are inflated with one or more compressed air canisters that are integrated in the display. Thus, the airbags are immediately inflated using compressed air. Deployment of the airbags may occur upon the display detecting that it is about to fall or as the display is falling. For example, if the display determines that its battery life is about to end and that one or more secondary adhesion mechanisms are not working or functioning properly, then the display deploys the airbags. In a related embodiment, base station 110 includes logic for determining when to cause the display to deploy its airbags. For example, base station 110 regularly receives (e.g., every five seconds) battery life data from the display and, optionally, any information about the quality of adhesion to a surface using one or more secondary adhesion mechanisms. Base station 110 sends, to the display, an airbag deployment instruction if the base station 110 determines, based on the battery life and information about the secondary adhesion mechanism, that the display might fall soon.

In the embodiment where airbags are deployed on the four corners of a display, the airbags together may create a clamshell around the display.

In a related embodiment, a display includes a parachute that is automatically deployed upon detection that the display is falling. The display also includes an air canister on the top of the display, which air canister is used to immediately inflate the parachute to ensure that the display will gently drop regardless of the height of the display.

In this parachute embodiment, the display may include a sensor that detects whether there is sufficient space for the parachute to deploy. For example, when placing a display near the ceiling (or other object), if the sensor detects that the top of the display is within a certain distance (e.g., five inches) of the ceiling, then the display will not activate any of its adhesion mechanisms. Only after detecting that there is sufficient space for the parachute to deploy will the display deploy one or more of its adhesion mechanisms.

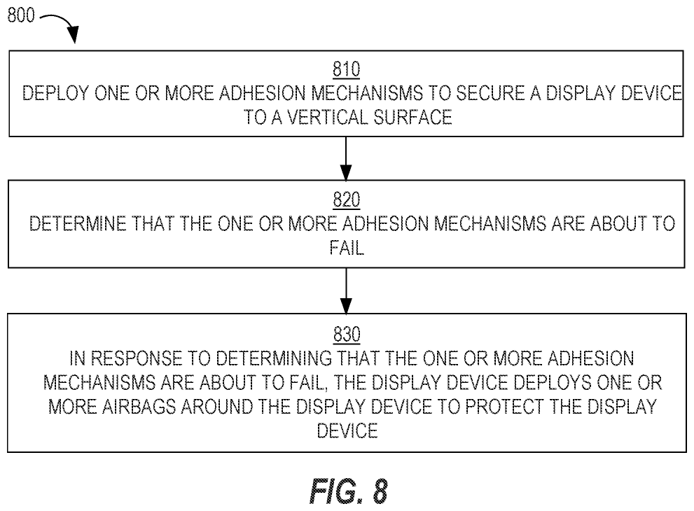

FIG. 8 is a flow diagram that depicts an example process 800 for automatically lowering a wireless display device that was attached to a vertical surface, in an embodiment.

At block 810, a display device deploys one or more adhesion mechanisms to secure the display device to a vertical surface. The one or more adhesion mechanisms may include a vacuum mechanism, a non-intrusive glue mechanism, and/or an industrial tape mechanism.

At block 820, it is determined that the one or more adhesion mechanisms are about to fail. Block 820 may involve determining that the battery life of one or more batteries in the display device are about to lose their charge. Alternatively, block 820 may involve determining that the display device is starting to move, for example, due to an adhesive losing its stickiness. Movement detection may be based on data from one or more accelerometers. Movement detection may be based on visual changes detected in consequent images captured by a camera of the display device. Alternatively, block 820 may involve determining a level of force on certain physical parts of an adhesion mechanism, where the level of force exceeds a threshold force level.

At block 830, in response to determining that the one or more adhesion mechanisms are about to fail, the display device deploys one or more airbags around the display device to protect the display device in case the one or more adhesion mechanisms fail. If the one or more adhesion mechanisms fail, then the display device might fall from its current position on the vertical surface.

### Resting Scenario

In an embodiment, display 120 is not attached to a vertical surface, nor is being moved to a position in which display 120 is to be attached to a vertical surface. Sensors in display 120 detect that no attachment (or adhesion) mechanisms have been deployed and other sensors (e.g., accelerometers) detect that display 120 is not moving. In this state, display 120 is considered to be in a resting state. Display 120 may be resting on the ground, on a table, or on a desk or other furniture. For example, the bottom of display 120 may be resting on a table and the top of display 120 may be leaning against a wall, ensuring that display 120 does not fall forward.

In an embodiment, when display 120 is at rest, display 120 sends, to base station 110, rest data that indicates that status. If display 120 is associated with a rest state, then base station 110 will not send, to display 120, airbag deployment instructions, attachment instructions, or other instructions that pertain to display 120 being attached to a vertical surface.

In an embodiment, base station 110 sends different warning messages to a user regarding low charge/power levels of display 120 depending on whether display 120 is at rest or whether display 120 is attached to a vertical surface. If the former, then a warning message to the user may be sent through one or more communication channels (e.g., text, app, etc.) with first text describing the low power situation and inviting the user to charge one or more batteries of display 120. If the latter, then a warning message to the user may be sent through multiple communications with second text that warns the user of consequences of display 120 losing battery power, such as potentially falling from a vertical surface.

### Display Stand Embodiment

In an embodiment, a display is configured to rest on a magnetic stand that includes a magnetic snap and a movable neck. Thus, the display includes an area to which the magnetic snap connects. That area of the display includes one or more magnets that will “snap” or connect to the magnets (or magnetic strip) in the magnetic stand.

In a related embodiment, the magnetic stand includes a power source that, when the display is magnetically connected to the magnetic stand, can charge one or more batteries that are inserted into the display.

In a related embodiment, when a display is connected to a magnetic stand, the display sends, to base station 110, stand connection data that indicates a status of the display relative to a stand. If the display is connected to a stand and not to a vertical surface, then base station 110 will not send, to the display, airbag deployment instructions, adhesion instructions, or other instructions that pertain to the display being attached to a vertical surface.

In an embodiment, the magnetic stand includes a power port for plugging a power source into the power ports, such as a USB-C plug that is connected to (or plugged into) an electrical outlet or to another power source. In this way, if the magnetic stand is plugged into a power source, then one or more batteries of a display that is magnetically snapped into the magnetic stand can charge.

In an embodiment, base station 110 sends different warning messages to a user regarding low power levels of a display depending on whether the display is on the magnetic stand or whether the display is on a vertical surface. If the former (and the magnetic stand is not charging the display), then a warning message to the user may be sent through one or more communication channels (e.g., text, app, etc.) with first text describing the low power situation and inviting the user to charge one or more batteries of the display. If the latter, then a warning message to the user may be sent through multiple communications with second text that warns the user of consequences of the display losing battery power, such as potentially falling from a vertical surface.

### Status and Battery Notifications

In an embodiment, a smartphone application receives notifications regarding status of each display as described above. More particularly, a mobile device with an application may receive notifications from base station 110 in control of one or more displays. For example, in a mesh network, base station 110 receives warnings from different displays concerning batteries, and then sends a notification to a user of a mobile device. When a battery is about to expire or reaches a predetermined level of charge, base station 110 may send a notification to each mobile device running the application.

In an embodiment, when a battery (or plurality of batteries) reaches a predetermined battery percentage, a hierarchy is determined for organizing any remaining battery charge. For example, a sleep mode may be entered. Alternatively, if the display is at rest, no attachment resources are necessary and all charge is provided to the display. Thus, a hierarchy includes maintaining the safety of the display by first determining if there is an attachment mechanism being used that requires battery support. Next, if no battery support is required, a sleep mode is entered and notifications of imminent power down are sent to the base station, users, and/or other displays or devices in the mesh network. In one embodiment, an ambient sensor or motion sensor may determine (using the camera or other sensor attached to the display) whether a user is watching the display. If it is determined that no user is present or that no movement is detected for a predetermined period of time, then a battery saving protocol may be implemented that powers down the display/displays automatically. Alternatively, a user may preprogram an application to determine what to do when it is determined that no users are present. For example, if a user is on vacation, a minimal battery usage may be implemented in which all battery charge is directed to maintaining an attachment to a surface, if necessary, and if the vacation is extended beyond an intended duration, in one embodiment, a fail-safe mechanism takes place in which the display or displays first share charge among each display for as long as possible to maintain an attachment if necessary, and then determine which display to safely drop first, second, third, fourth and so on to maintain the integrity of the display system.

### Modular Display System

In an embodiment, one or more displays include one or more sensors that detect whether a display is to be “snapped” together. A set of displays is snapped if each display displays a different portion of a video stream from base station 110. For example, four displays that are snapped together in a 2×2 grid display a different quarter of a video stream. For example, the top left display presents content that corresponds to the top left view of a television program; the bottom left display presents content that corresponds to the bottom left view of the television program; etc. Other display snapping configurations include a 3×3 grid and a 4×4 grid.

Detection of snapping may be performed in one or more ways. For example, a first display may detect (through one or more sensors) that a second display is touching the first display on a particular side of the first display or that the second display is within a few millimeters of the first display. As another example, a first display includes, on one side of the first display, one or more magnetic snaps in a particular order and a second display includes, on a corresponding side of the second display, one or more magnetic snaps in a reverse order so that the magnetic snaps of the first display attach to the magnetic snaps of the second display. When magnetic snaps from one display attach to magnetic snaps of another display, each display detects that it is connected to another display. This information (which may include an identity of each display, a snap status, and a location of the snap or connection) is transmitted to base station 110. This information is referred to as a “snap configuration.”

If base station 110 receives multiple snap configurations, one from each display that is snapped, then base station 110 constructs a mapping of the displays based on the multiple snap configurations. The mapping indicates which display is located relative to one or more of the other displays that are indicated in the snap configurations. Snapping and transmitting a content stream to multiple snapped devices is performed without requiring the presentation of a (e.g., complicated) user interface (with multiple display configuration options) to a user or the user providing input through the user interface.

Based on one or more snap configuration, base station 110 determines which portion of a content (e.g., video) stream should be sent to each snapped display, each snapped display receiving a different portion of that content stream. Alternatively, base station 110 sends the same content stream to each display but also sends instructions regarding which portion of that content stream to display. For example, base station 110 transmits (1) an instruction to a first snapped display to present the left side of a content stream and (2) an instruction to a second snapped display to present the right side of the same content stream. Base station 110 also transmits the content stream to both snapped displays.

In an embodiment, snapping of displays does not result in the displays showing different portions of the same content stream or even of base station 110 transmitting the same content stream to all snapped devices. Instead, user input is required to split a content stream into multiple portions, each portion being presented at the same time on different displays. An example of user input includes a voice command that a microphone in one or more of the displays detects and transmits the corresponding digital audio data to base station 110, which performs voice recognition on the digital audio data. Base station 110 may also determine whether the user is an authorized user and/or whether the user is authorized to perform this particular “split” operation.

Another example of user input to split a content stream is a user performing one or more hand gestures that one or more cameras of the two or more snapped devices capture. Detection that a captured hand gesture corresponds to a split command may be performed by one or more of the snapped devices or by base station 110, in which case one or more of the snapped devices send video data of the hand gesture(s) to base station 110, which analyzes the video data for pre-defined hand gestures. If the video data indicates a split command, then base station 110 transmits a split signal to the snapped devices.

In an embodiment, user input indicates which display's content is to be moved and split among a set of snapped devices to which the display belongs. User input may be a voice command such as, “Share the content of the lower right display among the snapped devices.”

User input may be one or more hand gestures, such as two hand palms facing a particular display (that is snapped to one or more other displays) with thumbs extended and the hands touching or almost touching and then moving the hands away from each other, indicating that the content of the pointed-to display is to be split among a set of snapped displays that includes the particular display. Video of each hand gesture is captured by a camera of a display and transmitted to base station 110. Base station 110 interprets the hand gesture in each captured video from each display and determines the intent of the hand gesture. For example, base station 110 analyzes a hand gesture in video data and compares the results of the analysis with a set of hand/finger gesture signatures stored in memory or persistent storage. If the detected hand gesture sufficiently matches one of the stored hand/finger gesture signatures, then base station 110 identifies the command that corresponds to that matched gesture signature. If there is no match, then base station 110 may send a message to the display from which the video data was transmitted (and/or to an application), requesting the user to re-perform the gesture.

In this example, the hand gesture to select a display is a single select command and the hand gesture to expand content to multiple displays is a single expand command. Base station 110 determines that these two hand gestures are connected based on a proximity of the displays that video captured the two hand gestures (or based on the same display capturing both hand gestures), based on the time between the two hand gestures, and/or based on the snapped nature of the display with one or more other displays.

Conversely, when undoing a split/expand operation, moving split content from multiple snapped displays to a single display may be initiated based on a user performing the opposite hand gestures, e.g., a first hand gesture comprising two hand palms that are initially spread out and a second hand gesture of moving those hand palms together, such that the hands touch or nearly touch.

User input may be a combination of a voice command and a hand gesture. In an example, upon detection of the snapping of two or more displays, one or more of the snapped displays presents an audible and/or visual question to a user, via one or more audio speakers and/or a screen of the one or more displays. For example, each display in a set of snapped displays presents a different number (e.g., between 1 and 9) (e.g., in the top right-hand corner of each screen) and the user is prompt to speak one of the presented numbers. Base station 110 identifies the display that presents the spoken number and then causes the content stream (or a portion thereof) that was being transmitted to that display to be transmitted to all displays in the set of snapped displays.

In an embodiment, base station 110 detects whether a set of snapped displays are in portrait mode or landscape mode and transmits a content stream to the set of snapped displays accordingly. For example, each display includes an accelerometer that is used to determine whether the display is in portrait mode or landscape mode and each display transmits this information to base station 110. If two displays are in portrait mode and are snapped together and base station 110 determines which of the two displays is to have its content stream split among the two displays, then base station 110 transmits the same content stream (or different portions thereof) to each display.

In an embodiment, a content stream split operation ceases in response to one or more detections. For example, the moving or unsnapping of a display from a set of snapped devices may cause a message to be transmitted from the display to base station 110. In response, base station 110 may automatically stop all streaming of the content stream to the set of snapped devices. Alternatively, in the scenario where base station is sending a different portion of the content stream to each display in the set, base station 110 sends the entire content stream to each display, causing each display in the set to present the entire content stream. Alternatively, in the scenario where base station is sending the entire content stream to each display in the set, base station 110 sends an instruction to each display to present the entire content stream.

### Additional Embodiments

In an embodiment, in a mesh network, base station 110 receives inputs from one or more displays 120 indicating where they are located and proximity. When two or more displays are snapped together, a remapping by base station 110 enables one or more videos, streams or interactive data to be displayed on the expanded mapping. Such a remapping may be in a frame buffer as applied to the displays to enable syncing of the streaming data from base station 110. In another example, if several displays are distributed throughout a network, and each display is in a different room, when the displays are moved to a central location, base station 110 detects that the displays have moved and remaps each display using the frame buffer wirelessly streaming protocols as a function of how the displays are reconnected.

In an embodiment, hall-effect sensors detect whether a display attaches or detaches from another display. Thus, base station 110 may enable any size display via remapping the displays. For example, in WiFi 6E or 7, high bandwidth capabilities allow transmission through walls and the like. Base station 110, in an embodiment, maps the displays to determine which content goes to which display. Using a combination of high bandwidth wireless technologies such as WiFi 6E, and WiFi 7 and the like along with remapping using frame buffer technologies, base station 110, once it detects that a snapping of several displays has occurred, may map each connected display to a single data stream, multiple data streams, or as directed by a user interface, smartphone application, or the like. Thus, the hall-effect sensors may be used to detect when different displays are attached or detached and when a remapping over frame buffering is required. In one embodiment, a single display may be snapped to other displays on all four sides, providing at least five displays connected to a mesh network.

In an embodiment, the displays may be snapped together in a portrait mode or a landscape mode, such that different possibilities include four 55-inch 4K displays (2x2) will for a 110 inch display with 8K resolution. Sixteen 55-inch 4K displays (4x4) will for a 220-inch display with 16K resolution. In other embodiments, different sized displays are combined only as limited by the mesh network and the WiFi technology available. Thus, a 32-inch 4K display may be combined with several 55-inch displays or vice versa to enable different size displays.

In an embodiment, the remapping instigated by snapping at least two displays together enables an on-the-fly orientation alteration detection that enables a streaming video or other interactive data stream to automatically display in an optimized view. For example, if a user is watching a TikTok video stream and an additional display is snapped below a first display, in an embodiment, base station 110 automatically remaps within a frame buffer for the data stream to take advantage of the detected additional display. Thus, the real time snapping together of the displays results in auto remapping of any video stream being driven to the first display in accordance with an orientation, and determines either portrait or landscape orientation, appropriate for the stream. For example, in some data streams, metadata may indicate a best orientation for viewing purposes or the like. Thus, metadata may assist in enabling on-the-fly real-time remapping of multiple displays.

### User Interaction

In an embodiment, one or more hand gestures are used to operate one or more displays that are wirelessly connected to base station 110. A camera that is attached to (or integrated into) a display captures video of a user. The camera may be activated when the display is turned on and presenting content. Additionally or alternatively, the camera may be activate in response to a voice command from an authorized user or from a user pressing a button to pop out the camera. Alternatively, a camera may always be on. The camera may be used not only for detecting hand/finger gestures, but also facial recognition. The video data that the camera generates may be analyzed by software executing within the display or may be wirelessly transmitted to base station 110 for analysis.

Example hand/finger gestures include raising a hand to pause content streaming, raising a hand to un-pause a paused content stream, using a single finger to browse through a display of options, using two fingers loving left or right to scroll through options, and using two fingers moving up or down to increase or decrease volume.

In an embodiment, a set of gestures may be used to affect multiple devices. For example, a first hand gesture selects a first display and a second hand gesture selects a second display and, based on a combination of the hand gestures, the content of the first display is moved to the second display such that the second display presents content that was being presented on the first display. Depending on the hand gestures (or just one of the two hand gestures), the content may continue to be presented on the first display or may cease to be presented on the first display. As a specific example, a grasping gesture (where an open hand is closed) that is directed at the first display effectively selects the content being presented on the first display and a throw gesture (where the closed hand is opened after or while the arm of the hand is moving) that is directed at the second display effectively selects the second display for presenting the content that was/is being presented on the first display. Again, each display sends captured video data to base station 110, which matches each detected gesture to a command and correlates two or more gestures based on timing and/or whether the same display or adjacent displays captured the gestures. In this example, base station 110 determines, based on the order, type, and/or timing of the two hand gestures, that the two hand gestures go together and the user intends to view a content stream (that was presented on one display) on another display.

In an embodiment, display switching is performed on the fly such that content that was being presented on one display is presented on another display that is also wirelessly connected to base station 110 when the other display detects the user. For example, if a user is watching a first display in a living room area of a house and wishes to move to a kitchen portion of the house where a second display is, the user is able to continue viewing the same content stream that may provide input that enables display switching.

Such display switching may be default enabled, meaning that the user does not have to provide any input to any device to allow for display switching. Instead, logic within base station 110 presumes that a user wishes to continue watching content regardless of the user's location. If the user wishes to view different content on a different display, then the user must provide input to view that different content, whether with a remote control, hand gestures, and/or voice commands.

In a non-default mode, a user provides input relative to a first display to enable display switching. For example, the user says, “Enable display switching” and a microphone on the first display converts the voice command to digital audio data that is sent to base station 110. Base station 110 may determine whether the user is authorized to enable display switching. If so, base station 110 may send, to one or more other displays, the content stream (that was/is being transmitted to the first display) and instructions to begin presenting that content stream.

In a related embodiment, during display switching, a content stream is paused while base station 110 detects that the user (e.g., that enabled display switching) is not in front of any display. When base station 110 detects that the user is in front of another display, the other display begins presenting the content stream beginning where the content stream paused. This pausing embodiment ensures that the user does not miss any content in the content stream. Such a pausing feature may be enabled and disabled based on user input, whether hand gesture, voice command, or app command (i.e., a command issued through an application installed on the user's personal device, such as a smartphone).

### User Interaction: Multi-Modal Controls

In an embodiment, a display is associated with multi-modal controls to modify what, how, and/or when content is presented on the display. Example modes of control include voice controls, touchscreen controls, hand gestures, a physical remote control, an application on personal device (e.g., smartphone), and finger caps. A display may include hardware and software (in conjunction with base station 110) to allow for two or more of these modes of control.

Regarding touchscreen controls, a display may present controls on a screen of the display, the controls include controls for modifying volume, changing content streams (e.g., cable or satellite TV channels), and adjusting video/audio settings of the display, such as brightness, contrast, etc. Such touchscreen controls may be presented automatically based on the user tapping the display or screen in a certain location, based on the user providing a voice command, and/or the display detecting that the user is approaching the display, such as using a camera to capture video of the user and sending the video data to base station 110 (or the display analyzing the video data itself).

Regarding app controls, a user downloads and installs a software application on the user's personal computing device (e.g., smartphone or wristwatch). The software application is provided by the same entity that manufactures base station 110 and display(s) 120. The software application is configured to communicate with a server of the entity over one or more computer networks, such as a cellular network and the Internet. The server is also connected to base station 110 over one or more computer networks. Controls that are presented via a graphical user interface on the software application allow the user to submit commands to the server, which determines which base station (of potentially many base stations across the world) is associated with the user or an account of the user. Thus, the commands may be associated with a user or account identifier. Additionally or alternatively, the commands may be associated with a display identifier that the software application detects when the personal device is in the vicinity of the display. The server identifies the base station associated with the same identifier(s) and forwards the commands to that base station, which forwards the commands to the display that the user is currently viewing. If multiple displays are communicatively coupled to the base station, then the base station determines to which of the multiple displays to forward the commands. The base station may infer which display the user desires to control based on one or more factors, such as which display is currently on (if there is only one currently on), which display is currently presenting content (if there is only one currently presenting content), which display is facing the user (e.g., using object detection or facial recognition), or which display is geographically closest to the user (e.g., based on GPS data associated with the display and with the personal device).

As an example of app controls, a software application displays multiple icons on a screen of a user's personal device, each icon corresponding to a different display that is communicatively coupled to base station 110. Another icon may represent a switch operation, another icon may represent an expand operation, and another icon may represent a follow operation. For example, a user may select a switch icon, then select a first display icon representing a first display that the user is currently watching, and then select a second display icon representing a second display that the user wishes to present the same content that the first display is/was presenting. These selections are transmitted from the personal device to base station 110 (e.g., over WiFi or via the Internet), which causes the content stream that is being transmitted to the first display to be transmitted to the second display. As another example, the user may select the expand operation and then select a first display icon representing a first display. These selections are transmitted from the personal device to base station 110, which causes the content stream to be sent to multiple displays that are snapped together. Base station 110 may determine which displays are snapped based on snap status information that base station 110 receives from each display in its private mesh network. As another example, the user may select the follow icon. This selection is transmitted from the personal device to base station 110, which causes the content stream to be sent to the display to which the user is detected to be in close proximity, such as using cameras of different displays and object detection and/or facial recognition technology implemented by base station 110.

In embodiment, finger caps enable user interaction with a display. Finger caps are hardware devices, one of which is designed to fit on a user's thumb and another on the user's finger, such as the index finger. A camera integrated in a display may visually detect finger caps that enable air writing on a display. For example, a user taps the finger caps together two times to enable searching for video content. While holding the finger caps together, the user then makes the letters T, O, P, G, U, N in the air. Position data of the finger caps is transmitted to the display (or base station 110). Base station 110 translates the position data into shapes or letters, and base station 110 performs a video search based on those letters and displays one or more video items that are associated with that sequence of letters. In addition to letters, finger caps may be used to draw shapes, which are associated with those commands. Again, translation of position data to shapes/letters and translation of shapes/letters to commands may be performed by the display, by base station 110, or both.

In an embodiment directed to a remote-agnostic display technology, combined voice, touch, and gesture interactive display over the mesh network make the use of a remote unnecessary. For example, each display in the mesh network may be supplied with a microphone for receiving voice instruction, a touch screen to enable a touch user interface, and a camera to enable facial recognition and gesture detection. The combination of user interaction may be coupled with the ability of a smartphone or other mobile device to function as a remote control in the event a user so chooses to interact using a remote control type device.

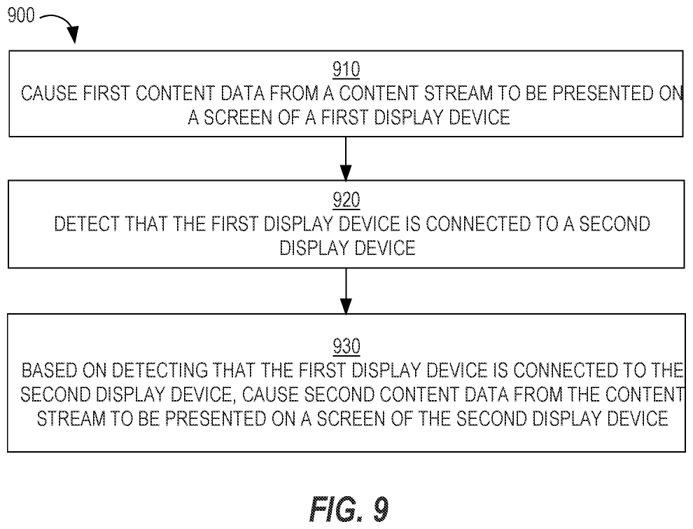

FIG. 9 is a flow diagram that depicts an example process 900 for sharing content among two or more display devices, in an embodiment. Process 900 may be performed by base station 110, the display devices individually or collectively, or a combination of the two.

At block 910, first content data from a content stream is caused to be presented on a screen of a first display device. The content stream may originate from base station 110 or from another source. For example, the content stream may be embedded in a WiFi signal generated by a router in a home environment, the router being connected to the Internet. Therefore, the content stream may originate from a website accessible through the Internet.

At block 920, it is detected that the first display device is connected to a second display device that is different than the first display device. Such detection may involve the first display device becoming magnetically attached to the second display device. Alternatively, such detection may involve sensors on the first display device detecting that the second display device is touching, or is within a certain distance from, the first display device. Alternatively, such detection may involve determining that the first display device may transmit content to the second display device. In other words, the two display devices are wirelessly connected.

At block 930, based on detecting that the first display device is connected to the second display device, second content data from the content stream is caused to be presented on a screen of the second display device. The second content data may be the same content data that is presented on the screen of the first display device. In this scenario, the first display device and the second display device present the same content simultaneously. Alternatively, the second content data may be a different portion of the same content stream that is being streamed to the first display device. For example, one half of the view of a content stream is sent to the first display device and the other half of the view of the content stream is sent to the second display device. When the first display device and the second display device are connected or touching, the combined screens present the entire view of the content stream.

Block 930 may also involve receiving digital image data that is generated by a camera that is integrated in the first display device. The digital image data reflects a hand/finger gesture made by a user of the first display device. The digital image data is analyzed to identify the type of gesture. The second content data is presented on the screen of the second display device also based on the type of gesture. For example, the gesture is a switch gesture that “grabs” the first display device and “throws” the grabbed content to the second display device. As a result, whatever is/was being streamed to the first display device is now streamed to the second display device. As another example, the gesture is an expand gesture that expands a content stream that is/was being streamed to the first display device is split up so that different portions of the content stream are sent to the first and second display devices.

### Hardware Overview

According to one embodiment, the techniques described herein are implemented by one or more special-purpose computing devices. The special-purpose computing devices may be desktop computer systems, portable computer systems, handheld devices, networking devices or any other device that incorporates hard-wired and/or program logic to implement embodiments herein.

For example, a computer system appropriate for base station 110 may include a Linux based computer system with a bus to enable communication with one or more processors or microprocessors. Base station 110 may include a memory such as random access memory (RAM) or other dynamic storage coupled to the bus for storing information and instructions to be executed by the one or more processors.

Each display may be a television including a receiver to connect to base station 110. Each display may also include a computer system to enable functionality described above such as vacuum technology, battery control technology, touch screen, facial recognition, and gestures.

Base station 110 may further implement a mesh network using logic, one or more ASICs or FPGAs, firmware and/or program logic which in combination with the computer system causes or programs computer system to be a special-purpose machine. According to one embodiment, the techniques herein are performed by base station 110 in response to a processor executing one or more sequences of one or more instructions contained memory. Such instructions may be read into main memory from another medium, such as a stream from a cloud-based storage medium over a network connection. In one embodiment, a stream may be received from a remote computer that may send the instructions over a high speed data line to a modem, such as a fiber connection including fiber to the curb, fiber to the home and the like as part of a communication interface that enables one-way or two-way data communication coupling to a network link. For example, communication interface may be an integrated services digital network (ISDN) card, cable modem, satellite modem, or a modem to provide a data communication connection to a local area network (LAN) card to provide a data communication connection to a compatible LAN.

Base station 110, as part of a private mesh network, may include several network links to provide data communication to one or more displays connected within the mesh network.

As part of base station 110 combined with one or more displays to form the mesh network may implement an operating system shared with the mesh network such that base station 110 manages execution of processes, memory allocation, file input and output (I/O), and device I/O for the computer system and each networked display. Additionally, the mesh network may be coupled to mobile devices having applications, or other software intended for use in combination with base station 110's computer system, that interact with a stored as a set of downloadable computer-executable instructions, for example, for downloading and installing content, such as from an Internet location (e.g., a content provider, such as Youtube, Roku, Apple TV, Hulu, TikTok, and any number of Web servers, an app stores, or other online services).

In one embodiment, base station 110 and/or each of the displays includes a graphical user interface (GUI) for receiving user commands and data without requiring a remote control via use of hand gestures, facial recognition, touch screen or alternatively over a mobile device running a remote control application.

According to one embodiment, the techniques described herein are implemented by one or more special-purpose computing devices. The special-purpose computing devices may be hard-wired to perform the techniques or may include digital electronic devices such as one or more application-specific integrated circuits (ASICs) or field programmable gate arrays (FPGAs) that are persistently programmed to perform the techniques or may include one or more general purpose hardware processors programmed to perform the techniques pursuant to program instructions in firmware, memory, other storage, or a combination. Such special-purpose computing devices may also combine custom hard-wired logic, ASICs, or FPGAs with custom programming to accomplish the techniques. The special-purpose computing devices may be desktop computer systems, portable computer systems, handheld devices, networking devices or any other device that incorporates hard-wired and/or program logic to implement the techniques.

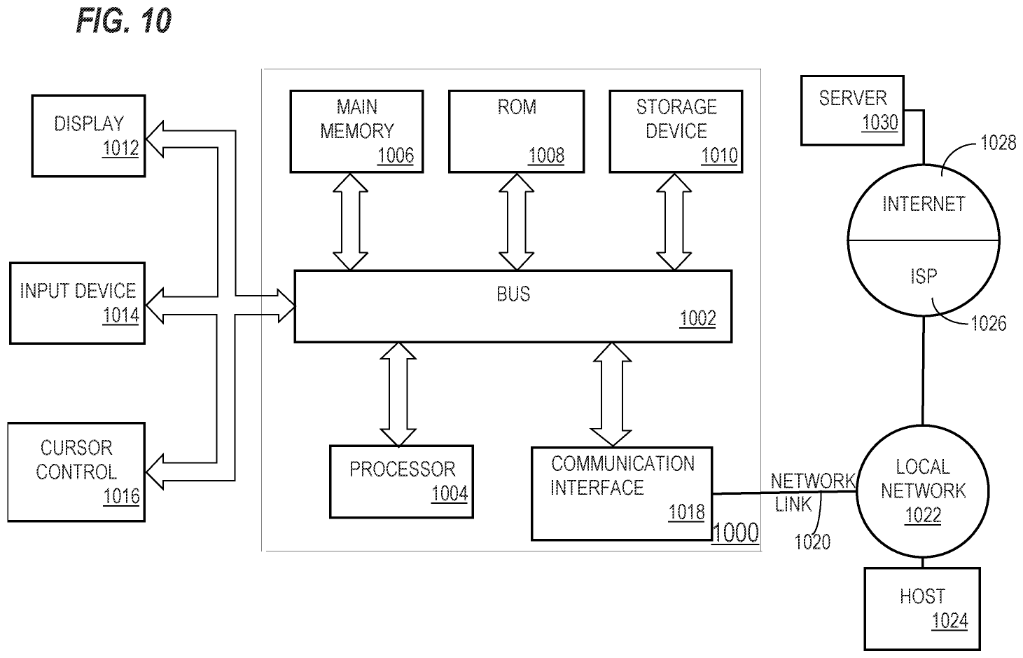

For example, FIG. 10 is a block diagram that illustrates computer system 1000 upon which various embodiments may be implemented. Computer system 1000 includes bus 1002 or other communication mechanism for communicating information, and hardware processor 1004 coupled with bus 1002 for processing information. Hardware processor 1004 may be, for example, a general-purpose microprocessor.

Computer system 1000 also includes a main memory 1006, such as a random-access memory (RAM) or other dynamic storage device, coupled to bus 1002 for storing information and instructions to be executed by processor 1004. Main memory 1006 also may be used for storing temporary variables or other intermediate information during execution of instructions to be executed by processor 1004. Such instructions, when stored in non-transitory storage media accessible to processor 1004, render computer system 1000 into a special-purpose machine that is customized to perform the operations specified in the instructions.

Computer system 1000 further includes a read only memory (ROM) 1008 or other static storage device coupled to bus 1002 for storing static information and instructions for processor 1004. A storage device 1010, such as a magnetic disk, optical disk, or solid-state drive is provided and coupled to bus 1002 for storing information and instructions.

Computer system 1000 may be coupled via bus 1002 to a display 1012, such as a cathode ray tube (CRT), for displaying information to a computer user. An input device 1014, including alphanumeric and other keys, is coupled to bus 1002 for communicating information and command selections to processor 1004. Another type of user input device is cursor control 1016, such as a mouse, a trackball, or cursor direction keys for communicating direction information and command selections to processor 1004 and for controlling cursor movement on display 1012. This input device typically has two degrees of freedom in two axes, a first axis (e.g., x) and a second axis (e.g., y), that allows the device to specify positions in a plane.

Computer system 1000 may implement the techniques described herein using customized hard-wired logic, one or more ASICs or FPGAs, firmware and/or program logic which in combination with the computer system causes or programs computer system 1000 to be a special-purpose machine. According to one embodiment, the techniques herein are performed by computer system 1000 in response to processor 1004 executing one or more sequences of one or more instructions contained in main memory 1006. Such instructions may be read into main memory 1006 from another storage medium, such as storage device 1010. Execution of the sequences of instructions contained in main memory 1006 causes processor 1004 to perform the process steps described herein. In alternative embodiments, hard-wired circuitry may be used in place of or in combination with software instructions.

The term “storage media” as used herein refers to any non-transitory media that store data and/or instructions that cause a machine to operate in a specific fashion. Such storage media may comprise non-volatile media and/or volatile media. Non-volatile media includes, for example, optical disks, magnetic disks, or solid-state drives, such as storage device 1010. Volatile media includes dynamic memory, such as main memory 1006. Common forms of storage media include, for example, a floppy disk, a flexible disk, hard disk, solid-state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge.

Storage media is distinct from but may be used in conjunction with transmission media. Transmission media participates in transferring information between storage media. For example, transmission media includes coaxial cables, copper wire and fiber optics, including the wires that comprise bus 1002. Transmission media can also take the form of acoustic or light waves, such as those generated during radio-wave and infra-red data communications.

Various forms of media may be involved in carrying one or more sequences of one or more instructions to processor 1004 for execution. For example, the instructions may initially be carried on a magnetic disk or solid-state drive of a remote computer. The remote computer can load the instructions into its dynamic memory and send the instructions over a telephone line using a modem. A modem local to computer system 1000 can receive the data on the telephone line and use an infra-red transmitter to convert the data to an infra-red signal. An infra-red detector can receive the data carried in the infra-red signal and appropriate circuitry can place the data on bus 1002. Bus 1002 carries the data to main memory 1006, from which processor 1004 retrieves and executes the instructions. The instructions received by main memory 1006 may optionally be stored on storage device 1010 either before or after execution by processor 1004.

Computer system 1000 also includes a communication interface 1018 coupled to bus 1002. Communication interface 1018 provides a two-way data communication coupling to network link 1020 that is connected to local network 1022. For example, communication interface 1018 may be an integrated services digital network (ISDN) card, cable modem, satellite modem, or a modem to provide a data communication connection to a corresponding type of telephone line. As another example, communication interface 1018 may be a local area network (LAN) card to provide a data communication connection to a compatible LAN. Wireless links may also be implemented. In any such implementation, communication interface 1018 sends and receives electrical, electromagnetic or optical signals that carry digital data streams representing various types of information.

Network link 1020 typically provides data communication through one or more networks to other data devices. For example, network link 1020 may provide a connection through local network 1022 to host computer 1024 or to data equipment operated by Internet Service Provider (ISP) 1026. ISP 1026 in turn provides data communication services through the worldwide packet data communication network now commonly referred to as the “Internet” 1028. Local network 1022 and Internet 1028 both use electrical, electromagnetic or optical signals that carry digital data streams. The signals through the various networks and the signals on network link 1020 and through communication interface 1018, which carry the digital data to and from computer system 1000, are example forms of transmission media.

Computer system 1000 can send messages and receive data, including program code, through the network(s), network link 1020 and communication interface 1018. In the Internet example, server 1030 might transmit a requested code for an application program through Internet 1028, ISP 1026, local network 1022 and communication interface 1018.

The received code may be executed by processor 1004 as it is received, and/or stored in storage device 1010, or other non-volatile storage for later execution.

### Software Overview

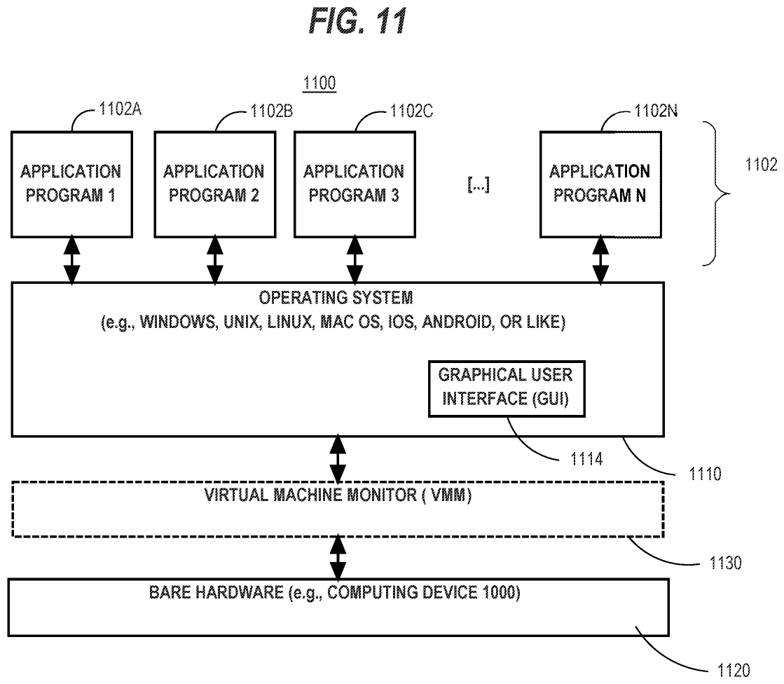

FIG. 11 is a block diagram of basic software system 1100 that may be employed for controlling the operation of computer system 1000. Software system 1100 and its components, including their connections, relationships, and functions, is meant to be exemplary only, and not meant to limit implementations of the example embodiment(s). Other software systems suitable for implementing the example embodiment(s) may have different components, including components with different connections, relationships, and functions.

Software system 1100 is provided for directing the operation of computing system 1000. Software system 1100, which may be stored in system memory (RAM) 1006 and on fixed storage (e.g., hard disk or flash memory) 1010, includes a kernel or operating system (OS) 1110.

The OS 1110 manages low-level aspects of computer operation, including managing execution of processes, memory allocation, file input and output (I/O), and device I/O. One or more application programs, represented as 1102A, 1102B, 1102C . . . 1102N, may be “loaded” (e.g., transferred from fixed storage 1010 into memory 1006) for execution by the system 1100. The applications or other software intended for use on computer system 1000 may also be stored as a set of downloadable computer-executable instructions, for example, for downloading and installation from an Internet location (e.g., a Web server, an app store, or other online service).

Software system 1100 includes graphical user interface (GUI) 1115, for receiving user commands and data in a graphical (e.g., “point-and-click” or “touch gesture”) fashion. These inputs, in turn, may be acted upon by system 1100 in accordance with instructions from operating system 1110 and/or application(s) 1102. GUI 1115 also serves to display the results of operation from OS 1110 and application(s) 1102, whereupon the user may supply additional inputs or terminate the session (e.g., log off).

OS 1110 can execute directly on the bare hardware 1120 (e.g., processor(s) 1004) of computer system 1000. Alternatively, a hypervisor or virtual machine monitor (VMM) 1130 may be interposed between the bare hardware 1120 and OS 1110. In this configuration, VMM 1130 acts as a software “cushion” or virtualization layer between OS 1110 and bare hardware 1120 of computer system 1000.

VMM 1130 instantiates and runs one or more virtual machine instances (“guest machines”). Each guest machine comprises a “guest” operating system, such as OS 1110, and one or more applications, such as application(s) 1102, designed to execute on the guest operating system. VMM 1130 presents the guest operating systems with a virtual operating platform and manages the execution of the guest operating systems.

In some instances, VMM 1130 may allow a guest operating system to run as if it is running on bare hardware 1120 of computer system 1100 directly. In these instances, the same version of the guest operating system configured to execute on bare hardware 1120 directly may also execute on VMM 1130 without modification or reconfiguration. In other words, VMM 1130 may provide full hardware and CPU virtualization to a guest operating system in some instances.

In other instances, a guest operating system may be specially designed or configured to execute on VMM 1130 for efficiency. In these instances, the guest operating system is “aware” that it executes on a virtual machine monitor. In other words, VMM 1130 may provide para-virtualization to a guest operating system in some instances.

A computer system process comprises an allotment of hardware processor time, and an allotment of memory (physical and/or virtual), the allotment of memory being for storing instructions executed by the hardware processor, for storing data generated by the hardware processor executing the instructions, and/or for storing the hardware processor state (e.g. content of registers) between allotments of the hardware processor time when the computer system process is not running. Computer system processes run under the control of an operating system and may run under the control of other programs being executed on the computer system.

### Cloud Computing

The term “cloud computing” is generally used herein to describe a computing model which enables on-demand access to a shared pool of computing resources, such as computer networks, servers, software applications, and services, and which allows for rapid provisioning and release of resources with minimal management effort or service provider interaction.

A cloud computing environment (sometimes referred to as a cloud environment, or a cloud) can be implemented in a variety of different ways to best suit different requirements. For example, in a public cloud environment, the underlying computing infrastructure is owned by an organization that makes its cloud services available to other organizations or to the general public. In contrast, a private cloud environment is generally intended solely for use by, or within, a single organization. A community cloud is intended to be shared by several organizations within a community; while a hybrid cloud comprises two or more types of cloud (e.g., private, community, or public) that are bound together by data and application portability.

Generally, a cloud computing model enables some of those responsibilities which previously may have been provided by an organization's own information technology department, to instead be delivered as service layers within a cloud environment, for use by consumers (either within or external to the organization, according to the cloud's public/private nature). Depending on the particular implementation, the precise definition of components or features provided by or within each cloud service layer can vary, but common examples include: Software as a Service (SaaS), in which consumers use software applications that are running upon a cloud infrastructure, while a SaaS provider manages or controls the underlying cloud infrastructure and applications. Platform as a Service (PaaS), in which consumers can use software programming languages and development tools supported by a PaaS provider to develop, deploy, and otherwise control their own applications, while the PaaS provider manages or controls other aspects of the cloud environment (i.e., everything below the run-time execution environment). Infrastructure as a Service (IaaS), in which consumers can deploy and run arbitrary software applications, and/or provision processing, storage, networks, and other fundamental computing resources, while an IaaS provider manages or controls the underlying physical cloud infrastructure (i.e., everything below the operating system layer). Database as a Service (DBaaS) in which consumers use a database server or Database Management System that is running upon a cloud infrastructure, while a DbaaS provider manages or controls the underlying cloud infrastructure and applications.

The above-described basic computer hardware and software and cloud computing environment presented for purpose of illustrating the basic underlying computer components that may be employed for implementing the example embodiment(s). The example embodiment(s), however, are not necessarily limited to any particular computing environment or computing device configuration. Instead, the example embodiment(s) may be implemented in any type of system architecture or processing environment that is capable of supporting the features and functions of the example embodiment(s) presented herein.

1. A method comprising:
making a first determination that one or more first batteries of a plurality of batteries, in a display device are in a blocked state;
making a second determination that one or more second batteries of the plurality of batteries are in an unblocked state;
based on the first determination and the second determination:
causing the one or more second batteries to be used for power before causing the one or more first batteries to be used for power, or
causing at least one of the one or more second batteries to transfer electrical power to at least one of the one or more first batteries;
wherein the method is performed by one or more processors.

2. The method of claim 1, further comprising:
receiving, at a base station, from the display device, blocked status data for each battery of the plurality of batteries;
wherein making the first and second determinations are performed by the base station and is based on the blocked status data for each battery of the plurality of batteries;
wherein causing comprises transmitting, from the base station to the display device:
battery discharge data that instructs the display device to use the one or more second batteries for electrical power before using the one or more first batteries for electrical power, or
power transfer data that instructs the display device to transfer the electrical power from the at least one of the one or more second batteries to the at least one of the one or more batteries.

3. The method of claim 1, wherein:
wherein making the first and second determinations are performed by the display device;
wherein causing is performed by the display device.

4. The method of claim 1, wherein the one or more first batteries are multiple batteries, wherein causing comprises causing the transfer of the electric power to each of the multiple batteries.

5. The method of claim 1, further comprising:
determining a battery level of each battery of the plurality of batteries in the display device;
wherein causing is also performed based on the battery level of each battery of the plurality of batteries.

6. The method of claim 1, further comprising:
determining an age of each battery of the plurality of batteries or a lifetime expectancy of each battery of the plurality of batteries;
wherein causing is also performed based on the age or lifetime expectancy of each battery of the plurality of batteries.

7. The method of claim 1, further comprising:
determining an attachment status of the display device, wherein the attachment status indicates whether the display device is attached to a vertical surface using one or more adhesion mechanisms;
wherein causing is also performed based on the attachment status of the display device.

8. The method of claim 1, further comprising:
based on data from one or more sensors in the display device, determining a blocked status of each battery in the plurality of batteries.

9. The method of claim 8, wherein the data is distance data that indicates a distance between a point on the display device and an object that is external to the display device.

10. The method of claim 1, wherein the plurality of batteries are hot-swappable batteries.

11. The method of claim 1, further comprising:
determining a remaining charge of a particular battery in the plurality of batteries;
performing a comparison between the remaining charge and a threshold charge;
based on the comparison, transmitting a notification that informs a user of the display device to recharge one or more of the plurality of batteries.

12. The method of claim 11, wherein the notification is a text message, an app message, an email message, or a message that is presented on a screen of the display device.

13. A method comprising:
for each insertable battery of a plurality of insertable batteries in a wireless display device, identifying a current charge of said each insertable battery;
for each internal battery of one or more internal batteries in the wireless display device, identifying a current charge of said each internal battery;
based on the current charge of each insertable battery and each internal battery, determining whether to transfer power from an insertable battery of the plurality of insertable batteries to an internal battery of the plurality of internal batteries.

14. The method of claim 13, further comprising:
based on the current charge of each insertable battery and each internal battery, determining whether to use one or more insertable batteries of the plurality of insertable batteries to power one or more functions of the wireless display device.

15. The method of claim 14, wherein the one or more functions is presenting content on a screen of the wireless display device.

16. The method of claim 13, further comprising:
detecting that the plurality of insertable batteries have been ejected from the wireless display device;
continuing to power one or more functions of the wireless display device using the one or more internal batteries.

17. The method of claim 13, further comprising:
determining a health of an insertable battery of the plurality of insertable batteries;
based on the health, determining to use one or more other insertable batteries, of the plurality of insertable batteries, before using the insertable battery to charge the one or more internal batteries to power one or more functions of the wireless display device.

18. The method of claim 13, further comprising:
based on the current charge of each insertable battery of the plurality of insertable batteries, determining to use each insertable battery of the plurality of insertable batteries in a round robin fashion.

19. The method of claim 13, further comprising:
based on the current charge of each insertable battery of the plurality of insertable batteries, determining a list of the plurality of insertable batteries that is ordered based on charge in descending order;
determining to use the first insertable battery in the list prior to using another insertable battery in the list.

20. The method of claim 13, further comprising:
storing a default discharge algorithm for discharging the plurality of insertable batteries;
receiving user input that specifies one or more changes to the default discharge algorithm;
in response to receiving the user input, implementing a custom discharge algorithm, that is based on the one or more changes, for discharging the plurality of insertable batteries.

21. A method comprising:
determining a charge of each battery of a first plurality of batteries of a first wireless display device;
determining a charge of each battery of a second plurality of batteries of a second wireless display device that is separate from the first wireless display device;
based on the charges of the first and second plurality of batteries and in response to determining that the first wireless display device can share charge with the second wireless display device, transferring charge from a first battery, of the first plurality of batteries, to a second battery of the second plurality of batteries.

22. The method of claim 1, further comprising:
determining batteries of the first and second plurality of batteries are blocked and which are not blocked;
determining to use batteries that are not blocked before using batteries that are blocked.

23. One or more non-transitory storage media storing instructions which, when executed by one or more computing devices, cause performance of the method recited in claim 1.

24. One or more non-transitory storage media storing instructions which, when executed by one or more computing devices, cause performance of the method recited in claim 13.

25. One or more non-transitory storage media storing instructions which, when executed by one or more computing devices, cause performance of the method recited in claim 21.
